(19) United States
(12) Patent Application Publication
(10) Pub. No.: US 2025/0233558 A1
(43) Pub. Date: Jul. 17, 2025

(54) AMPLIFICATION CIRCUIT AND COMMUNICATION DEVICE

(71) Applicant: Murata Manufacturing Co., Ltd., Kyoto (JP)

(72) Inventors: Kenji TAHARA, Kyoto (JP); Kae YAMAMOTO, Kyoto (JP)

(21) Appl. No.: 19/170,245

(22) Filed: Apr. 4, 2025

Related U.S. Application Data
(63) Continuation of application No. PCT/JP2023/034727, filed on Sep. 25, 2023.

(30) Foreign Application Priority Data
Oct. 12, 2022 (JP) 2022-163786

(51) Int. Cl. H03F 1/02; H03F 3/21

(52) U.S. Cl. CPC H03F 1/0211; H03F 3/211; H03F 2203/21191

(57) ABSTRACT

An amplification circuit includes a power supply voltage terminal that receives a power supply voltage V1, a power supply voltage terminal that receives a power supply voltage V2 having a different voltage level from that of the power supply voltage V1, digital control terminals that receive digital control signals based on an envelope signal, a power amplifier connected to the power supply voltage terminal, a power amplifier connected to the power supply voltage terminal, a synthetic circuit connected to the power amplifiers, a biasing circuit that supplies bias currents, and a switching circuit connected to the digital control terminals and configured to switch connection and disconnection between the biasing circuit and the power amplifier and to switch connection and disconnection between the biasing circuit and the power amplifier. Each of the power amplifiers includes multiple cascode-connected amplification transistors.

### CROSS REFERENCE TO RELATED APPLICATION

This is a continuation of International Application No. PCT/JP2023/034727 filed on Sep. 25, 2023 which claims priority from Japanese Patent Application No. 2022-163786 filed on Oct. 12, 2022. The contents of these applications are incorporated herein by reference in their entireties.

### BACKGROUND OF THE DISCLOSURE

### Field of the Disclosure

The present disclosure relates to an amplification circuit and a communication device.

### Description of the Related Art

An improvement in efficiency (power added efficiency) of a power amplification circuit has been attempted in recent years by applying envelope tracking (ET) thereto. There has been disclosed a digital ET technology to supply power supply voltages having multiple discrete voltage levels to an ET system.

U.S. Pat. No. 9,755,672 discloses a power supply modulation circuit (a tracker circuit) that supplies power supply voltages to an amplification circuit based on an envelope signal. The above-mentioned power supply modulation circuit includes a switched capacitor circuit that generates multiple voltages having different voltage levels, and an output switching circuit that selects and outputs at least one of the multiple voltages.

### BRIEF SUMMARY OF THE DISCLOSURE

However, when a high-frequency signal is amplified with an amplification circuit by using the ET as disclosed in U.S. Pat. No. 9,755,672, amplification characteristics (efficiency and gain) of the amplification circuit are assumed to be deteriorated by capacitance components of wiring that supplies a power supply voltage from the tracker circuit to the amplification circuit.

Given the circumstances, the present disclosure provides an amplification circuit and a communication device which suppress deterioration of amplification characteristics when using the ET.

An amplification circuit according to an aspect of the present disclosure includes: a first power supply voltage terminal that receives a first power supply voltage being a direct-current voltage; a second power supply voltage terminal that receives a second power supply voltage being a direct-current voltage and having a different voltage level from a voltage level of the first power supply voltage; a digital control terminal that receives a digital control signal based on an envelope signal; a first power amplifier connected to the first power supply voltage terminal; a second power amplifier connected to the second power supply voltage terminal; a synthetic circuit connected to an output end of the first power amplifier and an output end of the second power amplifier; a biasing circuit configured to supply a first bias current to the first power amplifier and to supply a second bias current to the second power amplifier; and a switching circuit connected to the digital control terminal and configured to switch connection and disconnection between the biasing circuit and the first power amplifier and to switch connection and disconnection between the biasing circuit and the second power amplifier, and each of the first power amplifier and the second power amplifier includes a plurality of cascode-connected amplification elements.

According to the present disclosure, it is possible to provide an amplification circuit and a communication device which suppress deterioration of amplification characteristics when using the ET.

### BRIEF DESCRIPTION OF THE SEVERAL VIEWS OF THE DRAWINGS

FIG. 1A is a graph showing an example of a change in power supply voltage in an average power tracking mode.

FIG. 1B is a graph showing an example of a change in power supply voltage in an analog envelope tracking mode.

FIG. 1C is a graph showing an example of a change in power supply voltage in a digital envelope tracking mode.

FIG. 2 is a circuit configuration diagram of an amplification circuit and a communication device according to an embodiment.

FIG. 3A is a circuit configuration diagram of a synthetic circuit according to the embodiment.

FIG. 3B is a circuit configuration diagram of a synthetic circuit according to Modified Example 1 of the embodiment.

FIG. 4 shows diagrams depicting an envelope waveform, an output voltage, and an on-and-off relation of switches of the amplification circuit according to the embodiment.

FIG. 5A is a circuit state diagram in a case where a high-frequency signal to be inputted to the amplification circuit according to the embodiment has a first envelope value.

FIG. 5B is a circuit state diagram in a case where the high-frequency signal to be inputted to the amplification circuit according to the embodiment has a second envelope value.

FIG. 5C is a circuit state diagram in a case where the high-frequency signal to be inputted to the amplification circuit according to the embodiment has a third envelope value.

FIG. 6 is a circuit configuration diagram of an amplification circuit and a communication device according to Comparative Example 1.

FIG. 7 is a circuit configuration diagram of an amplification circuit and a communication device according to Modified Example 2 of the embodiment.

FIG. 8A is a circuit configuration diagram of a synthetic circuit according to the Modified Example 2 of the embodiment.

FIG. 8B is a circuit configuration diagram of a synthetic circuit according to Modified Example 3 of the embodiment.

FIG. 9 shows diagrams depicting an envelope waveform, an output voltage, and an on-and-off relation of switches of the amplification circuit according to the Modified Example 2 of the embodiment.

FIG. 10A is a circuit state diagram in a case where a high-frequency signal to be inputted to the amplification circuit according to the Modified Example 2 of the embodiment has a first envelope value.

FIG. 10B is a circuit state diagram in a case where the high-frequency signal to be inputted to the amplification circuit according to the Modified Example 2 of the embodiment has a second envelope value.

FIG. 10C is a circuit state diagram in a case where the high-frequency signal to be inputted to the amplification circuit according to the Modified Example 2 of the embodiment has a third envelope value.

FIG. 10D is a circuit state diagram in a case where the high-frequency signal to be inputted to the amplification circuit according to the Modified Example 2 of the embodiment has a fourth envelope value.

FIG. 10E is a circuit state diagram in a case where the high-frequency signal to be inputted to the amplification circuit according to the Modified Example 2 of the embodiment has a fifth envelope value.

FIG. 10F is a circuit state diagram in a case where the high-frequency signal to be inputted to the amplification circuit according to the Modified Example 2 of the embodiment has a sixth envelope value.

FIG. 10G is a circuit state diagram in a case where the high-frequency signal to be inputted to the amplification circuit according to the Modified Example 2 of the embodiment has a seventh envelope value.

FIG. 11 is a diagram showing relations between envelope waveforms and output voltages of amplification circuits according to the Modified Example 2 of the embodiment and Comparative Example 2.

### DETAILED DESCRIPTION OF THE DISCLOSURE

An embodiment of the present disclosure will be described below in detail by using the drawings. Note that the embodiment described below represents a comprehensive or specific example. Numerical values, shapes, materials, components, layouts and states of connection of the components, and the like illustrated in the embodiment described below are mere examples and are not intended to limit the present disclosure.

Here, the respective drawings are schematic drawings subjected to emphasis, omission, or ratio adjustment as appropriate in order to demonstrate the present disclosure. The drawings are not always precisely illustrated, and the shapes, positional relations, or ratios thereof may be different from actual ones in some cases. In the respective drawings, substantially the same structures are denoted by the same reference signs and overlapping explanations thereof may be omitted or simplified in some cases.

In a circuit configuration of the present disclosure, a state of being “connected” includes not only a case of being directly connected with a connection terminal and/or a wiring conductor but also a case of being electrically connected with another circuit element interposed therebetween. A state of being “connected between A and B” means a state of being located between A and B and connected to both A and B.

Meanwhile, in the present disclosure, a “signal path” means a transmission line constructed by wiring to propagate a high-frequency signal, an electrode directly connected to the wiring, and a terminal directly connected to any of the wiring and the electrode, and so forth.

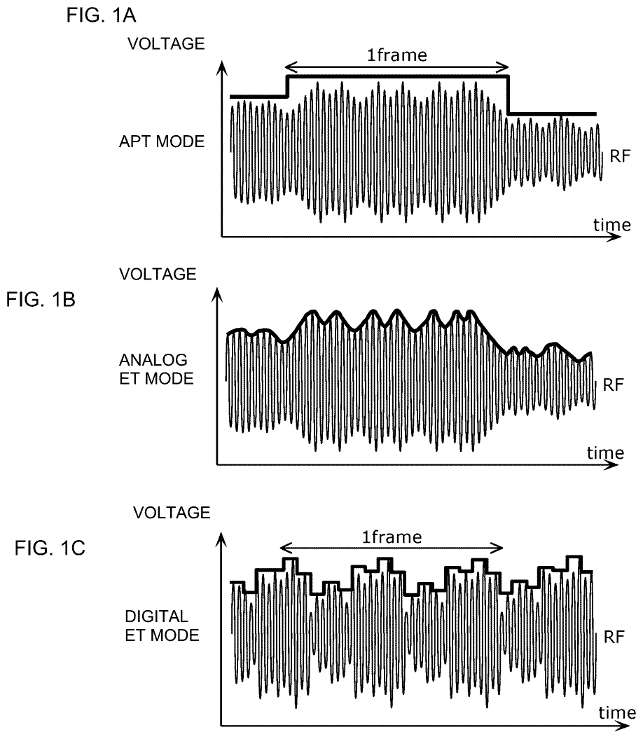

First, a tracking mode for supplying a variable power supply voltage, which is dynamically adjusted with passage of time based on a high-frequency signal, to a power amplifier will be described as a technique for amplifying the high-frequency signal at high efficiency. The tracking mode is a mode of dynamically adjusting a power supply voltage to be applied to an amplification circuit. Although there are several types of the tracking mode, an average power tracking (APT) mode and envelope tracking (ET) modes (inclusive of an analog ET mode and a digital ET mode) will be described herein with reference to FIG. 1A to FIG. 1C. In FIG. 1A to FIG. 1C, a horizontal axis represents time and a vertical axis represents a voltage. Meanwhile, a thick solid line represents a power supply voltage and a thin solid line (a waveform) represents a modulation wave.

FIG. 1A is a graph showing an example of a change in power supply voltage in the APT mode. In the APT mode, the power supply voltage is changed into multiple discrete voltage levels by the frame. As a consequence, a power supply voltage signal forms a rectangular wave. In the APT mode, the voltage level of the power supply voltage is determined based on average output power. Note that the voltage level may be changed in the APT mode by a unit (such as a sub-frame, a slot, and a symbol) smaller than the frame. The APT in which the voltage level is changed by the symbol may also be referred to as symbol power tracking (SPT) in some cases.

A frame in a case where a sub-cattier interval is equal to 15 kHz, for example, is a unit of a high-frequency signal having a length of 10 milliseconds and includes ten sub-frames. The sub-frame is a unit of the high-frequency signal having a length of 1 millisecond and includes two slots. The slot is a unit of the high-frequency signal having a length of 0.5 millisecond and includes six or seven symbols. The symbol is a unit of the high-frequency signal having a length of 71 microseconds, for example, and includes a cyclic prefix (CP).

In the SPT mode, the level of the power supply voltage is modulated by the symbol. In this instance, the voltage level is changed in a section of the CP. For example, the voltage level is changed to a higher level in the CP at a first symbol and the voltage level is changed to a lower level in the CP at a second symbol. Here, the voltage level does not have to be changed in the subsequent symbol. The level of the power supply voltage can be modulated based on a data signal of each symbol section.

FIG. 1B is a graph showing an example of a change in power supply voltage in the analog ET mode. The analog ET mode is an example of conventional ET modes. As shown in FIG. 1B, in the analog ET mode, an envelope of a modulation wave is tracked by continuously changing the power supply voltage. In the analog ET mode, the power supply voltage is determined based on an envelope signal.

The envelope signal is a signal that represents the envelope of the modulation wave. An envelope value is expressed by a square root of (I²+Q²), for example. Here, values (I, Q) represent a constellation point. The constellation point is a point that represents the signal modulated by digitation modulation on a constellation diagram. The values (I, Q) are determined by a baseband integrated circuit (BBIC) based on transmission information, for example.

FIG. 1C is a graph showing an example of a change in power supply voltage in the digital ET mode. As shown in FIG. 1C, in the digital ET mode, an envelope of a modulation wave is tracked by changing the power supply voltage into multiple discrete voltage levels in one frame. As a consequence, the power supply voltage signal forms a rectangular wave. In the digital ET mode, the power supply voltage level is selected or set up from the multiple discrete voltage levels based on the envelope signal.

### Embodiment

### (1 Configurations of Amplification Circuit 1 and Communication Device 4)

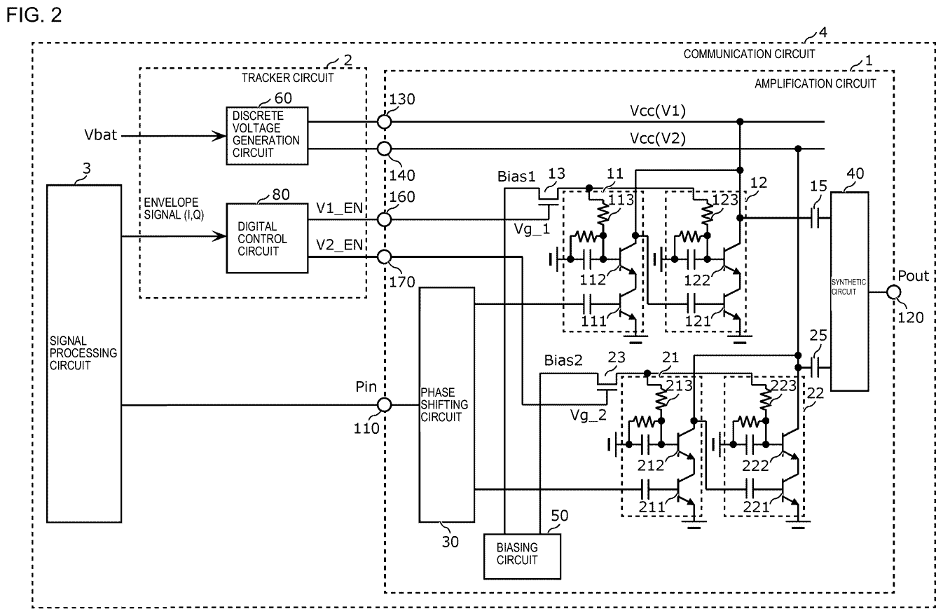

An amplification circuit 1 and a communication device 4 according to the present embodiment will be described with reference to FIG. 2.

FIG. 2 is a circuit configuration diagram of the amplification circuit 1 and the communication device 4 according to the embodiment. The communication device 4 according to the present embodiment corresponds to user equipment (UE) in a cellular network, which is typically any of a cellular phone, a smartphone, a tablet computer, a wearable device, and the like. Here, the communication device 4 may be any of an Internet-of-Things (IoT) sensor device, a medical/healthcare device, a vehicle, an unmanned aerial vehicle (UAV) (or so-called a drone), and an automated guided vehicle (AGV) instead.

A circuit configuration of the communication device 4 will be described to begin with. As shown in FIG. 2, the communication device 4 according to the present embodiment includes the amplification circuit 1, a tracker circuit 2, and a signal processing circuit 3.

The signal processing circuit 3 is an example of a signal processing circuit that processes the high-frequency signal. The signal processing circuit 3 includes a control unit that controls the amplification circuit 1 and the tracker circuit 2. To be more precise, the signal processing circuit 3 subjects a transmission signal to signal processing by up-converting and the like, and outputs a high-frequency transmission signal generated by the signal processing to the amplification circuit 1. Meanwhile, the signal processing circuit 3 outputs the envelope signal, which indicates the envelope of the modulation wave of the high-frequency signal, to the tracker circuit 2. Here, part or all of functions as the control unit of the signal processing circuit 3 may be implemented on the outside of the signal processing circuit 3 or may be implemented in the amplification circuit 1 and the tracker circuit 2, for example.

The tracker circuit 2 can supply the multiple discrete voltage based on the tracking mode to the amplification circuit 1. The digital ET mode can be used as the tracking mode. However, the tracking mode is not limited thereto. The tracker circuit 2 includes a discrete voltage generation circuit 60 and a digital control circuit 80.

For example, the discrete voltage generation circuit 60 is configured to generate multiple discrete voltages having the multiple discrete voltage levels, respectively. The discrete voltage generation circuit 60 is a switched capacitor circuit including multiple capacitors and multiple switches, for example. Here, the discrete voltage generation circuit 60 only needs to have such a configuration that can output two types of direct-current voltages having different voltage levels at the same time.

The digital control circuit 80 can control the amplification circuit 1 based on the envelope signal from the signal processing circuit 3. To be more precise, the digital control circuit 80 generates digital control logic/line (DCL) signals (V1_EN, V2_EN), for example, based on the envelope signal received from the signal processing circuit 3.

Here, the digital control circuit 80 may be included in the signal processing circuit 3 instead of being included in the tracker circuit 2.

The amplification circuit 1 includes power amplifiers 11, 12, 21, and 22, switches 13 and 23, capacitors 15 and 25, a phase shifting circuit 30, a synthetic circuit 40, a biasing circuit 50, a signal input terminal 110, a signal output terminal 120, power supply voltage terminals 130 and 140, and digital control terminals 160 and 170.

The signal input terminal 110 is connected to the signal processing circuit 3 and the phase shifting circuit 30, and transmits the high-frequency signal outputted from the signal processing circuit 3 to the phase shifting circuit 30. The signal output terminal 120 is connected to the synthetic circuit 40 and an antenna (not illustrated), and outputs the high-frequency signal amplified by the amplification circuit 1 to the antenna, for example.

The power supply voltage terminal 130 is an example of a first power supply voltage terminal, which is connected to the tracker circuit 2 as well as the power amplifiers 11 and 12, receives a power supply voltage V1 generated by the tracker circuit 2, and transmits the power supply voltage V1 to the power amplifiers 11 and 12. The power supply voltage terminal 140 is an example of a second power supply voltage terminal, which is connected to the tracker circuit 2 as well as the power amplifiers 21 and 22, receives a power supply voltage V2 generated by the tracker circuit 2, and transmits the power supply voltage V2 to the power amplifiers 21 and 22. The power supply voltage V1 is an example of a first power supply voltage. The power supply voltage V2 is an example of a second power supply voltage, which has a different voltage level from that of the power supply voltage V1. Here, each of the power supply voltages V1 and V2 is not changed based on the envelope value of the high-frequency signal to be inputted to the amplification circuit 1.

Here, both the power supply voltages V1 and V2 are the direct-current voltages, and the voltages at different voltage levels are applied to the power supply voltage terminal 130 that receives the power supply voltage V1 and to the power supply voltage terminal 140 that receives the power supply voltage V2 at the same time. Although both the power supply voltages V1 and V2 are the direct-current voltages, the present disclosure is not limited to a configuration to apply the voltage at the same voltage level through the entire time to each of the power supply voltage terminals 130 and 140.

The digital control terminals 160 and 170 receive digital control signals generated by the tracker circuit 2. The digital control signal is a signal based on the envelope signal of the high-frequency signal inputted from the signal input terminal 110, for example. Here, the digital control terminals 160 and 170 may be consolidated into a single control terminal.

Each of the power amplifiers 11, 12, 21, and 22 includes an amplification transistor. For example, the amplification transistor is a bipolar transistor such as a heterojunction bipolar transistor (HBT) or a field effect transistor such as a metal-oxide-semiconductor field effect transistor (MOSFET).

For example, the power amplifiers 11, 12, 21, and 22 are class-A (or class-AB) amplification circuits that can perform amplification at all power levels of the high-frequency signal. Here, the power amplifiers 11, 12, 21, and 22 may be class-C amplification circuits instead.

The power amplifier 11 includes transistors 111 and 112, and a resistor 113. The transistors 111 and 112 are n-type bipolar transistors (amplification elements), for example. A base of the transistor 111 is connected to the phase shifting circuit 30 with a capacitor interposed therebetween, an emitter of the transistor 111 is connected to the ground, and a collector of the transistor 111 is connected to an emitter of the transistor 112. A base of the transistor 112 is connected to the biasing circuit 50 with the resistor 113 as well as the switch 13 interposed therebetween. Meanwhile, the base of the transistor 112 is connected to the ground with a capacitor interposed therebetween, and is grounded in terms of the high frequency. A collector of the transistor 112 is connected to the power supply voltage terminal 130. That is to say, the power amplifier 11 includes the cascode-connected transistors 111 and 112.

The power amplifier 12 is an example of a first power amplifier, which includes transistors 121 (a first amplification element) and 122 (a second amplification element), and a resistor 123. The transistors 121 and 122 are n-type bipolar transistors (amplification elements), for example. A base (a first control terminal) of the transistor 121 is connected to the phase shifting circuit 30 with a capacitor as well as the power amplifier 11 interposed therebetween, an emitter (a first terminal) of the transistor 121 is connected to the ground, and a collector (a second terminal) of the transistor 121 is connected to an emitter (a third terminal) of the transistor 122. A base (a second control terminal) of the transistor 122 is connected to the biasing circuit 50 with the resistor 123 as well as the switch 13 interposed therebetween. Meanwhile, the base of the transistor 122 is connected to the ground with a capacitor interposed therebetween, and is grounded in terms of the high frequency. A collector (a fourth terminal) of the transistor 122 is connected to the power supply voltage terminal 130, and is connected to the synthetic circuit 40 with the capacitor 15 interposed therebetween. That is to say, the power amplifier 12 includes the cascode-connected transistors 121 and 122.

Note that the amplification circuit 1 does not always have to include the power amplifier 11. Alternatively, instead of the power amplifiers 11 and 12, the amplification circuit 1 may be provided with three or more cascade-connected power amplifiers including the power amplifier 12.

The power amplifier 21 includes transistors 211 and 212, and a resistor 213. The transistors 211 and 212 are n-type bipolar transistors (amplification elements), for example. A base of the transistor 211 is connected to the phase shifting circuit 30 with a capacitor interposed therebetween, an emitter of the transistor 211 is connected to the ground, and a collector of the transistor 211 is connected to an emitter of the transistor 212. A base of the transistor 212 is connected to the biasing circuit 50 with the resistor 213 as well as the switch 23 interposed therebetween. Meanwhile, the base of the transistor 212 is connected to the ground with a capacitor interposed therebetween, and is grounded in terms of the high frequency. A collector of the transistor 212 is connected to the power supply voltage terminal 140. That is to say, the power amplifier 21 includes the cascode-connected transistors 211 and 212.

The power amplifier 22 is an example of a second power amplifier, which includes transistors 221 (a third amplification element) and 222 (a fourth amplification element), and a resistor 223. The transistors 221 and 222 are n-type bipolar transistors (amplification elements), for example. A base (a third control terminal) of the transistor 221 is connected to the phase shifting circuit 30 with a capacitor as well as the power amplifier 21 interposed therebetween, an emitter (a fifth terminal) of the transistor 221 is connected to the ground, and a collector (a sixth terminal) of the transistor 221 is connected to an emitter (a seventh terminal) of the transistor 222. A base (a fourth control terminal) of the transistor 222 is connected to the biasing circuit 50 with the resistor 223 as well as the switch 23 interposed therebetween. Meanwhile, the base of the transistor 222 is connected to the ground with a capacitor interposed therebetween, and is grounded in terms of the high frequency. A collector (an eighth terminal) of the transistor 222 is connected to the power supply voltage terminal 140, and is connected to the synthetic circuit 40 with the capacitor 25 interposed therebetween. That is to say, the power amplifier 22 includes the cascode-connected transistors 221 and 222.

Note that the amplification circuit 1 does not always have to include the power amplifier 21. Alternatively, instead of the power amplifiers 21 and 22, the amplification circuit 1 may be provided with three or more cascade-connected power amplifiers including the power amplifier 22.

Since each of the power amplifiers 11, 12, 21, and 22 has the cascode-connected structure, the amplification circuit 1 can secure high amplification gain regarding high-frequency signals in a millimeter-wave band and a sub-terahertz band.

The phase shifting circuit 30 is configured to distribute the high-frequency signal inputted from the signal input terminal 110, and to output the distributed signals to the power amplifiers 11 and 21. In this instance, the phase shifting circuit 30 adjusts phases of the distributed signals. Note that the amplification circuit 1 does not always have to include the phase shifting circuit 30.

The synthetic circuit 40 is connected to an output end of the power amplifier 12 and to an output end of the power amplifier 22, and is configured to synthesize the high-frequency signal outputted from the power amplifier 12 and the high-frequency signal outputted from the power amplifier 22, and to output the synthesized high-frequency signal to the signal output terminal 120.

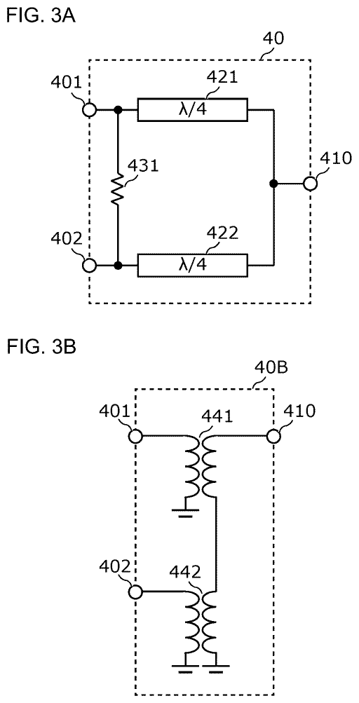

FIG. 3A is a circuit configuration diagram of the synthetic circuit 40 according to the embodiment. As shown in FIG. 3A, the synthetic circuit 40 includes input terminals 401 and 402, an output terminal 410, λ/4 phase shifting lines 421 and 422, and a resistor 431. One end of the λ/4 phase shifting line 421 is connected to the input terminal 401, and another end of the λ/4 phase shifting line 421 is connected to the output terminal 410. One end of the λ/4 phase shifting line 422 is connected to the input terminal 402, and another end of the λ/4 phase shifting line 422 is connected to the output terminal 410. One end of the resistor 431 is connected to the input terminal 401, and another end of the resistor 431 is connected to the input terminal 402. The input terminal 401 is connected to the output end of the power amplifier 12 with the capacitor 15 interposed therebetween. The input terminal 402 is connected to the output end of the power amplifier 22 with the capacitor 25 interposed therebetween. The output terminal 410 is connected to the signal output terminal 120. According to the above-described configuration of the synthetic circuit 40, the high-frequency signal outputted from the power amplifier 12 and the high-frequency signal outputted from the power amplifier 22 are subjected to current synthesis by the synthetic circuit 40, and the high-frequency signal subjected to the current synthesis is outputted from the signal output terminal 120. Here, the synthetic circuit 40 is not limited to the above-described circuit configuration and may instead be a synthetic circuit 40B according to Modified Example 1 described below, for example.

FIG. 3B is a circuit configuration diagram of the synthetic circuit 40B according to the Modified Example 1 of the embodiment. As shown in FIG. 3B, the synthetic circuit 40B includes the input terminals 401 and 402, the output terminal 410, and transformers 441 and 442. Each of the transformers 441 and 442 includes a primary coil and a secondary coil. One end of the primary coil of the transformer 441 is connected to the input terminal 401, and another end thereof is connected to the ground. One end of the secondary coil of the transformer 441 is connected to the output terminal 410, and another end thereof is connected to one end of the secondary coil of the transformer 442. One end of the primary coil of the transformer 442 is connected to the input terminal 402, and another end thereof is connected to the ground. Another end of the secondary coil of the transformer 442 is connected to the ground. The input terminal 401 is connected to the output end of the power amplifier 12 with the capacitor 15 interposed therebetween. The input terminal 402 is connected to the output end of the power amplifier 22 with the capacitor 25 interposed therebetween. The output terminal 410 is connected to the signal output terminal 120. According to the above-described configuration of the synthetic circuit 40B, the high-frequency signal outputted from the power amplifier 12 and the high-frequency signal outputted from the power amplifier 22 are subjected to voltage synthesis by the synthetic circuit 40B, and the high-frequency signal subjected to the voltage synthesis is outputted from the signal output terminal 120.

Back to FIG. 2, the components of the amplification circuit 1 will be described.

The biasing circuit 50 is configured to supply a first bias current to the power amplifiers 11 and 12 and to supply a second bias current to the power amplifiers 21 and 22. The first bias current is supplied to the power amplifiers 11 and 12 with the switch 13 interposed therebetween, and the second bias current is supplied to the power amplifiers 21 and 22 with the switch 23 interposed therebetween.

The switch 13 is an example of a first switch, which is connected to the digital control terminal 160 and configured to switch connection and disconnection between the biasing circuit 50 and the power amplifiers 11 and 12. To be more precise, the switch 13 includes a control terminal and two terminals. The control terminal is connected to the digital control terminal 160. One of the terminals is connected to the biasing circuit 50, and the other terminal is connected to the power amplifiers 11 and 12.

The switch 23 is an example of a second switch, which is connected to the digital control terminal 170 and configured to switch connection and disconnection between the biasing circuit 50 and the power amplifiers 21 and 22. To be more precise, the switch 23 includes a control terminal and two terminals. The control terminal is connected to the digital control terminal 170. One of the terminals is connected to the biasing circuit 50, and the other terminal is connected to the power amplifiers 21 and 22.

The switches 13 and 23 are connected to the digital control terminals 160 and 170, thus constituting a switching circuit that switches connection and disconnection of the biasing circuit 50 to and from the respective power amplifiers.

Here, the amplification circuit 1 may include a first logic circuit between the digital control terminals 160 as well as 170 and the switch 13, and a second logic circuit between the digital control terminals 160 as well as 170 and the switch 23. The first logic circuit converts the DCL signals (V1_EN, V2_EN) applied to the digital control terminals 160 and 170 into a gate signal to be supplied to the switch 13. The second logic circuit converts the DCL signals (V1_EN, V2_EN) applied to the digital control terminals 160 and 170 into a gate signal to be supplied to the switch 23.

For example, in the case of the DCL signals V1_EN=1 and V2_EN=0, the first logic circuit outputs a gate signal (Vg_1=1) to set the switch 13 to a conducting state, and the second logic circuit outputs a gate signal (Vg_2=0) to set the switch 23 to a non-conducting state. Meanwhile, in the case of the DCL signals V1_EN=0 and V2_EN=1, the first logic circuit outputs a gate signal (Vg_1=0) to set the switch 13 to the non-conducting state, and the second logic circuit outputs a gate signal (Vg_2=1) to set the switch 23 to the conducting state. In the meantime, in the case of the DCL signals V1_EN=1 and V2_EN=1, the first logic circuit outputs the gate signal (Vg_1=1) to set the switch 13 to the conducting state, and the second logic circuit outputs the gate signal (Vg_2=1) to set the switch 23 to the conducting state.

Here, each digital control signal to be supplied to one of the digital control terminals 160 and 170 may be a parallel data signal instead of a serial data signal such as a digital control signal in accordance with a source synchronous method. Parallel supply of the DCL signals V1_EN and V2_EN to the respective digital control terminals 160 and 170 makes it possible to switch on and off of the respective power amplifiers at high speed. Thus, it is possible to deal with a wide channel band width of the high-frequency signal in the millimeter-wave band and the sub-terahertz band.

Note that the serial data signal means a data signal to be transmitted bit by bit on one signal line or one line. On the other hand, the parallel data signal means a data signal to be transmitted simultaneously in parallel on multiple signal lines or multiple lines.

### (2 Operation of Amplification Circuit 1)

Next, an amplification operation of the amplification circuit 1 will be described.

When the high-frequency signal is inputted from the base of the amplification transistor constituting each of the power amplifiers 11, 12, 21, and 22 and the high-frequency signal is outputted from the collector thereof, the output power Pout of the high-frequency signal and a power supply voltage Vcc satisfy the following relational expression of Formula 1:

$${P}_{out} ( dBm ) = 10 log ( \frac{{( 2 Vcc - Vsat )}^{2}}{8 {R}_{L} \times {10}^{- 3}} ) . \qquad ( Formula 1 )$$

In the above-mentioned Formula 1, code Vsat denotes a collector-emitter voltage, and code R_{L} denotes load impedance that is equal to 50 (Ω), for example.

When the amplification circuit 1 receives the power voltage in accordance with an ET method as in the present embodiment, the amplification transistor is operated in a saturated region and the value Vsat is therefore substantially equal to 0. Accordingly, when the value Vsat=0 is assigned to the Formula 1, the output power Pout (W) is expressed as in Formula 2, and moreover, a voltage component Pout (V) of the output power is expressed as in Formula 3:

$${P}_{out} ( W ) = k 1 \times {Vcc}^{2} ; and \qquad ( Formula 2 )$$

$${P}_{out} ( V ) = k 2 \times Vcc . \qquad ( Formula 3 )$$

Here, each of values k1 and k2 is a constant.

As shown in the Formula 3, in the case of the ET method, the voltage component Pout (V) of the output power of the high-frequency signal is expressed as a linear function of the power supply voltage Vcc.

Here, assuming that the voltage component Pout (V) of the output voltage from the power amplifier 12 to which the power supply voltage V1 is supplied is Po_(V1) and the voltage component Pout (V) of the output voltage from the power amplifier 22 to which the power supply voltage V2 is supplied is Po_(V2), a voltage component obtained by synthesizing the voltage component Po_(V1) of the power amplifier 12 and the voltage component Po_(V2) of the power amplifier 22 is expressed by Formula 4 based on a relation of the Formula 3:

$$Po\_ ( V 1 ) + Po\_ ( V 2 ) = k 2 \times ( V 1 + V 2 ) = Po\_ ( V 1 + V 2 ) . \qquad ( Formula 4 )$$

That is to say, the synthesized voltage component of the power amplifier 12 and the power amplifier 22 is equivalent to a voltage component in a case of supplying a power supply voltage (V1+V2) to any one of the power amplifiers 12 and 22.

Here, assuming that the power supply voltage V1=1 V and the power supply voltage V2=2 V, for example, the amplification circuit 1 can output the power to one power amplifier in the cases of supplying power supply voltages 1 V (V1), 2 V (V2), and 3 V (V1+V2) by using the power amplifiers 12 and 22.

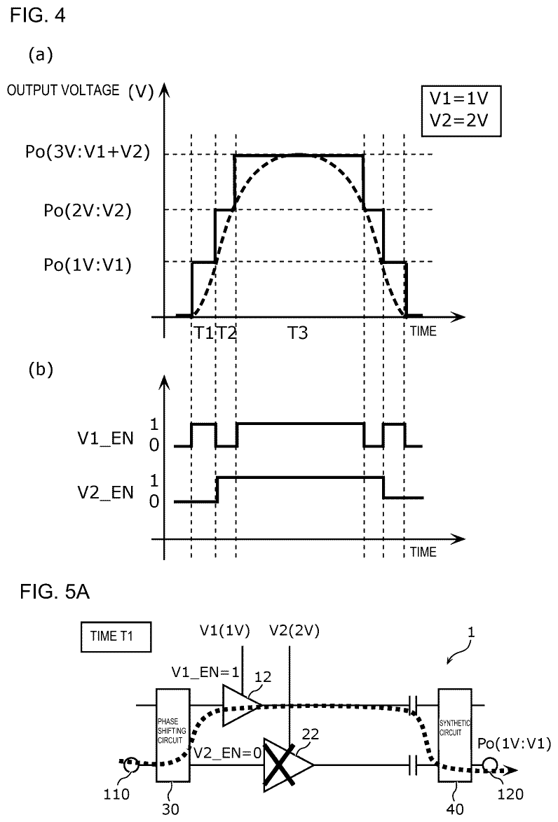

FIG. 4 shows diagrams depicting an envelope waveform, an output voltage, and an on-and-off relation of the switches of the amplification circuit 1 according to the embodiment. Part (a) of FIG. 4 depicts the envelope waveform (a dashed line) of the high-frequency signal to be inputted to the amplification circuit 1 and the output voltage (V) (the voltage component of the output power) of the amplification circuit 1, and part (b) of FIG. 4 depicts waveforms of the DCL signals (V1_EN, V2_EN).

Here, an assumption is made in FIG. 4 that the power supply voltage V1=1 V and the power supply voltage V2=2 V. That is to say, the power supply voltage V1 is lower than the power supply voltage V2.

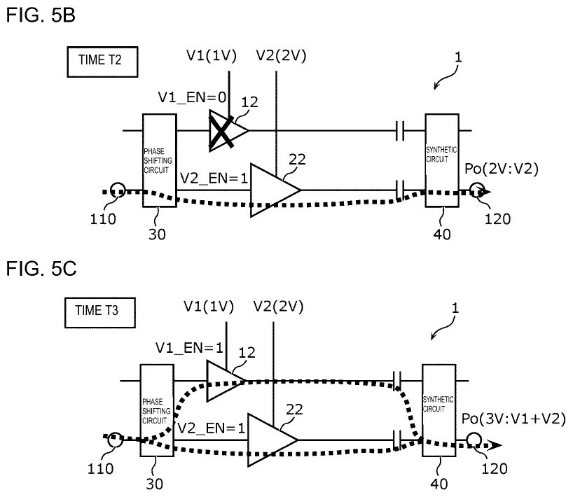

FIG. 5A is a circuit state diagram in a case where the high-frequency signal to be inputted to the amplification circuit 1 according to the embodiment has a first envelope value. Specifically, at time T1 when the envelope value indicating a magnitude of the envelope signal of the high-frequency signal to be inputted to the amplification circuit 1 is equal to a first value, the switch 13 is set to the conducting state and the switch 23 is set to the non-conducting state by setting the DCL signals V1_EN=1 and V2_EN=0. Accordingly, the first bias current is supplied to the power amplifier 12 which is thus set to the on-state, and the second bias current is not supplied to the power amplifier 22 which is thus set to the off-state. Hence, the power amplifier 12 outputs the output voltage Po_(1 V: V1), and the amplification circuit 1 outputs the output voltage Po_(1 V: V1).

FIG. 5B is a circuit state diagram in a case where the high-frequency signal to be inputted to the amplification circuit 1 according to the embodiment has a second envelope value. Specifically, at time T2 when the envelope value of the high-frequency signal to be inputted to the amplification circuit 1 is equal to a second value being larger than the first value, the switch 13 is set to the non-conducting state and the switch 23 is set to the conducting state by setting the DCL signals V1_EN=0 and V2_EN=1. Accordingly, the first bias current is not supplied to the power amplifier 12 which is thus set to the off-state, and the second bias current is supplied to the power amplifier 22 which is thus set to the on-state. Hence, the power amplifier 22 outputs the output voltage Po_(2 V: V2), and the amplification circuit 1 outputs the output voltage Po_(2 V: V2).

FIG. 5C is a circuit state diagram in a case where the high-frequency signal to be inputted to the amplification circuit 1 according to the embodiment has a third envelope value. Specifically, at time T3 when the envelope value of the high-frequency signal to be inputted to the amplification circuit 1 is equal to a third value being larger than the second value, the switch 13 is set to the conducting state and the switch 23 is set to the conducting state by setting the DCL signals V1_EN=1 and V2_EN=1. Accordingly, the first bias current is supplied to the power amplifier 12 which is thus set to the on-state, and the second bias current is supplied to the power amplifier 22 which is thus set to the on-state. Hence, the power amplifier 12 outputs the output voltage Po_(1 V: V1) and the power amplifier 22 outputs the output voltage Po_(2 V: V2). The output voltage Po_(1 V: V1) and the output voltage Po_(2 V: V2) are synthesized by the synthetic circuit 40, and the amplification circuit 1 outputs the output voltage Po_(3 V: V1+V2).

According to the above-described operation of the amplification circuit 1, the on-off operations of the respective power amplifiers are executed so as to correspond to the envelope value of the high-frequency signal to be inputted to the amplification circuit 1 in the state where the power supply voltage V1 being the direct-current voltage is constantly supplied to the power amplifiers 11 and 12, and the power supply voltage V2 being the direct-current voltage is constantly supplied to the power amplifiers 21 and 22. In this instance, the power supply voltages to be supplied to the power amplifiers 12 and 22 include two types of the power supply voltages V1 and V2. Nonetheless, when the amplification circuit 1 is regarded as a single power amplifier, the power supply voltages to be supplied to the amplification circuit 1 can be considered to include three types of the power supply voltages V1, V2, and (V1+V2). Accordingly, the power supply voltage corresponding to the envelope signal is supplied to the amplification circuit 1 at high accuracy and high speed without blunting the waveform, so that efficiency and gain of the amplification circuit 1 can be improved.

Here, in the case where the power supply voltage V1 is lower than the power supply voltage V2, the size of the amplification transistor included in the power amplifier 22 may be larger than the size of the amplification transistor included in the power amplifier 12.

According to this configuration, it is possible to execute the amplification operations across the entire signal range from a small signal range to a large signal range while suppressing signal distortion.

Meanwhile, in the case where the power supply voltage V1 is lower than the power supply voltage V2, a cross-sectional area of wiring that connects the power amplifier 22 to the power supply voltage terminal 140 may be larger than a cross-sectional area of wiring that connects the power amplifier 12 to the power supply voltage terminal 130.

According to this configuration, it is possible to suppress waveform blunting of the power supply voltages V1 and V2 more appropriately.

Here, the size of the amplification transistor included in the power amplifier is defined as an area of a forming region of the amplification transistor in the case of plan view (perspective view) of a principal surface of a substrate where the power amplifier is located. In the meantime, the size of the amplification transistor depends on the number of stages of transistor elements constituting the amplification transistor, the number of cells, or the number of fingers. Accordingly, the state where the size of the amplification transistor is large is a state where at least one of the large number of the stages of the transistor elements, the large number of the cells, and the large number of the fingers hold true.

Meanwhile, the area of the forming region of the amplification transistor can be measured by recognizing regions of n-type and p-type semiconductors in an image of the amplification transistor shot by projecting X-rays in a normal direction to the principal surface of the substrate.

In the meantime, amplification transistors constituting amplifiers may have a structure in which multiple transistor elements are connected in parallel. When each of the multiple transistor elements is an emitter-grounded bipolar transistor, in this case, the number of the amplification transistors is determined by the number of collector terminals. In other words, the number of the amplification transistors and the number of the collector terminals have a one-to-one correspondence.

Meanwhile, the cross-sectional area of the wiring means any of: (1) a value obtained by averaging cross-sectional areas in a case of cutting the wiring in a direction orthogonal to a direction of flow of a current across the direction of flow of the current on the wiring; (2) a value obtained by averaging the cross-sectional areas in the case of cutting the wiring in the direction orthogonal to a direction of flow of the current while sampling at predetermined intervals along the direction of flow of the current on the wiring; and (3) a value obtained by averaging the cross-sectional areas in the case of cutting the wiring in the direction orthogonal to the direction of flow of the current while sampling at several arbitrary locations along the direction of flow of the current on the wiring.

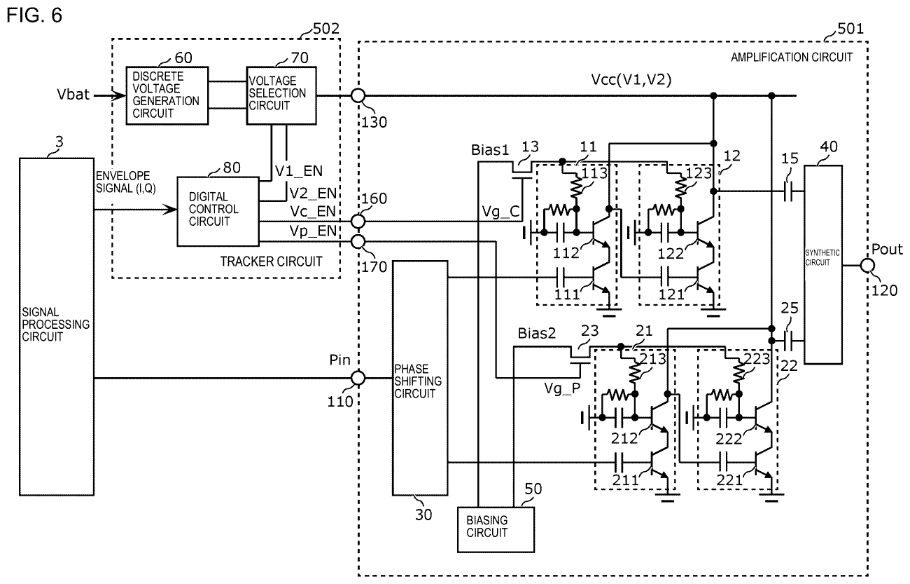

FIG. 6 is a circuit configuration diagram of an amplification circuit 501 according to Comparative Example 1. To be more precise, FIG. 6 shows the amplification circuit 501, a tracker circuit 502, and the signal processing circuit 3 according to the Comparative Example 1.

The amplification circuit 501 includes the power amplifiers 11, 12, 21, and 22, the switches 13 and 23, the capacitors 15 and 25, the phase shifting circuit 30, the synthetic circuit 40, the biasing circuit 50, the signal input terminal 110, the signal output terminal 120, the power supply voltage terminal 130, and the digital control terminals 160 and 170. As compared to the amplification circuit 1 according to the embodiment, the amplification circuit 501 according to the Comparative Example 1 has a different wiring configuration for supplying the power supply voltage. The amplification circuit 501 according to the Comparative Example 1 will be described below while mainly focusing on the different configuration from the amplification circuit 1 according to the embodiment.

The power supply voltage terminal 130 is connected to the tracker circuit 502 as well as the power amplifiers 11, 12, 21, and 22, receives the power supply voltages V1 and V2 generated by the tracker circuit 502, and transmits the power supply voltages V1 and V2 to the power amplifiers 11, 12, 21, and 22. The power supply voltages to be supplied to the power amplifiers 11, 12, 21, and 22 are switched between the power supply voltage V1 and the power supply voltage V2 at high speed based on the envelope signal.

The tracker circuit 502 includes the discrete voltage generation circuit 60, a voltage selection circuit 70, and the digital control circuit 80.

The voltage selection circuit 70 is configured to output at least one of the multiple discrete voltages, which are generated by the discrete voltage generation circuit 60 based on the envelope signal, selectively to the amplification circuit 1. The voltage selection circuit 70 is controlled based on a digital control signal outputted from the digital control circuit 80.

The digital control circuit 80 can control the voltage selection circuit 70 and the amplification circuit 1 based on the envelope signal from the signal processing circuit 3. To be more precise, the digital control circuit 80 generates the DCL signals (V1_EN, V2_EN) based on the envelope signal received from the signal processing circuit 3.

According to the amplification circuit 501 of the Comparative Example 1, the power supply voltages to be supplied to the respective power amplifiers 11, 12, 21, and 22 are switched in response to the envelope signal, and the presence or absence of the supply of the bias current is switched at the same time. In this instance, a waveform of the power supply voltage being changed at high speed is blunted by a capacitance component of the wiring that supplies the power supply voltage from the tracker circuit 502 to the amplification circuit 501, whereby the amplification characteristics (efficiency and gain) of the amplification circuit 1 are presumably deteriorated.

On the other hand, according to the amplification circuit 1 of the present embodiment, the power supply voltage V1 being the direct-current voltage is constantly supplied to the power amplifiers 11 and 12, and the power supply voltage V2 being the direct-current voltage is constantly supplied to the power amplifiers 21 and 22. That is to say, the direct-current voltage is constantly applied to power supply voltage supply wiring that connects the power supply voltage terminals 130 and 140 to the respective power amplifiers. Accordingly, it is possible to keep the waveforms of the power supply voltages V1 and V2 from being blunted by wiring capacitance of the power supply voltage supply wiring. In the meantime, switching the presence or absence of the supply of the bias current to be supplied to each power amplifier is equivalent to making the power supply voltage to be supplied to the power amplifier being in the on-state variable by using the digital control signals based on the envelope signal. Thus, it is possible to provide the amplification circuit 1 that suppresses deterioration of the amplification characteristics when using the digital ET.

Meanwhile, the voltage selection circuit 70 for selecting the power supply voltage to be supplied to the amplification circuit 501 out of the multiple discrete voltages is provided to the tracker circuit 502 according to the Comparative Example 1. In contrast, the tracker circuit 2 according to the present embodiment does not need the voltage selection circuit 70. Accordingly, it is possible to downsize the communication device 4.

### (3 Amplification Circuit 1A and Communication Device 4A According to Modified Example 2)

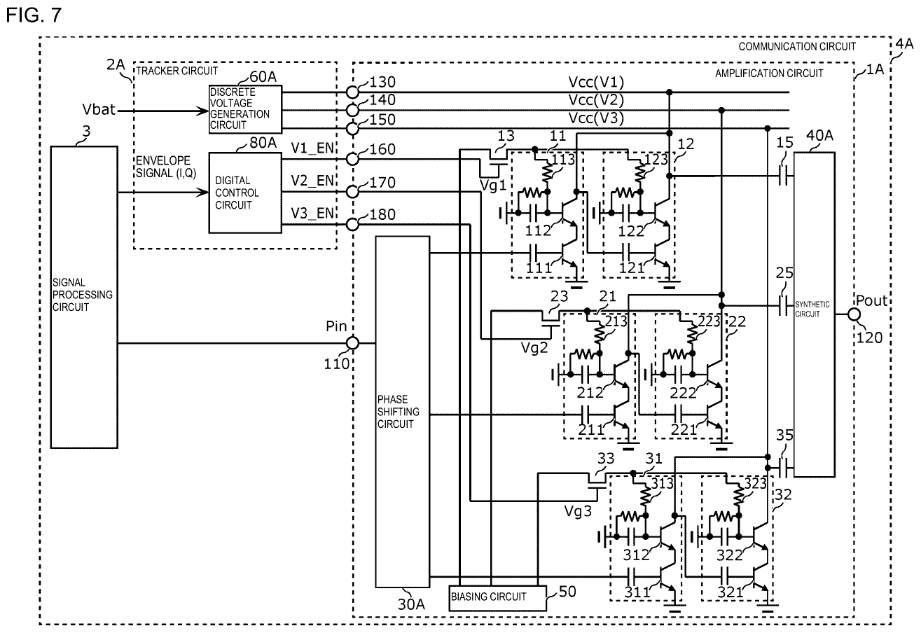

Next, an amplification circuit 1A and a communication device 4A according to Modified Example 2 of the present embodiment will be described with reference to FIGS. 7 to 11.

FIG. 7 is a circuit configuration diagram of the amplification circuit 1A and the communication device 4A according to the Modified Example 2 of the embodiment. As shown in FIG. 7, the communication device 4A includes the amplification circuit 1A, a tracker circuit 2A, and the signal processing circuit 3. As compared to the communication device 4 according to the embodiment, the communication device 4A according to the present modified example has different configurations of the amplification circuit 1A and the tracker circuit 2A. The configurations of the amplification circuit 1A and the tracker circuit 2A will therefore be mainly described below.

The tracker circuit 2A can supply the multiple discrete voltage levels based on the tracking mode to the amplification circuit 1A. The digital ET mode can be used as the tracking mode. However, the tracking mode is not limited thereto. The tracker circuit 2A includes a discrete voltage generation circuit 60A and a digital control circuit 80A.

The discrete voltage generation circuit 60A is configured to generate multiple discrete voltages having the multiple discrete voltage levels, respectively.

The digital control circuit 80A can control the amplification circuit 1A based on the envelope signal from the signal processing circuit 3. To be more precise, the digital control circuit 80A generates DCL signals (V1_EN, V2_EN, V3_EN), for example, based on the envelope signal received from the signal processing circuit 3.

The amplification circuit 1A includes power amplifiers 11, 12, 21, 22, 31, and 32, switches 13, 23, and 33, capacitors 15, 25, and 35, a phase shifting circuit 30A, a synthetic circuit 40A, the biasing circuit 50, the signal input terminal 110, the signal output terminal 120, power supply voltage terminals 130, 140, and 150, and digital control terminals 160, 170, and 180.

The power supply voltage terminal 130 is an example of the first power supply voltage terminal, which is connected to the tracker circuit 2A as well as the power amplifiers 11 and 12, receives the power supply voltage V1 generated by the tracker circuit 2A, and transmits the power supply voltage V1 to the power amplifiers 11 and 12. The power supply voltage terminal 140 is an example of the second power supply voltage terminal, which is connected to the tracker circuit 2A as well as the power amplifiers 21 and 22, receives the power supply voltage V2 generated by the tracker circuit 2A, and transmits the power supply voltage V2 to the power amplifiers 21 and 22. The power supply voltage terminal 150 is an example of a third power supply voltage terminal, which is connected to the tracker circuit 2A as well as the power amplifiers 31 and 32, receives a power supply voltage V3 generated by the tracker circuit 2A, and transmits the power supply voltage V3 to the power amplifiers 31 and 32. The power supply voltages V1, V2, and V3 are examples of the direct-current voltages, which have different voltage levels from one another. Here, each of the power supply voltages V1, V2, and V3 is not changed based on the envelope value of the high-frequency signal to be inputted to the amplification circuit 1A.

Here, each of the power supply voltages V1, V2, and V3 is the direct-current voltage, and the voltages at different voltage levels are applied to the power supply voltage terminal 130 that receives the power supply voltage V1, the power supply voltage terminal 140 that receives the power supply voltage V2, and the power supply voltage terminal 150 that receives the power supply voltage V3 at the same time. Although all the power supply voltages V1, V2, and V3 are the direct-current voltages, the present disclosure is not limited to a configuration to apply the voltage at the same voltage level through the entire time to each of the power supply voltage terminals 130, 140, and 150.

The digital control terminals 160, 170, and 180 receive digital control signals generated by the tracker circuit 2A. The digital control signal is a signal based on the envelope signal of the high-frequency signal inputted from the signal input terminal 110, for example. Here, the digital control terminals 160, 170, and 180 may be consolidated into a single control terminal or consist of two control terminals.

Each of the power amplifiers 11, 12, 21, 22, 31, and 32 includes an amplification transistor. For example, the amplification transistor is a bipolar transistor such as the HBT or a field effect transistor such as the MOSFET. For example, the power amplifiers 11, 12, 21, 22, 31, and 32 are the class-A (or class-AB) amplification circuits that can perform amplification at all power levels of the high-frequency signal. Here, the power amplifiers 11, 12, 21, 22, 31, and 32 may be class-C amplification circuits instead.

The power amplifier 31 includes transistors 311 and 312, and a resistor 313. The transistors 311 and 312 are n-type bipolar transistors (amplification elements), for example. A base of the transistor 311 is connected to the phase shifting circuit 30A with a capacitor interposed therebetween, an emitter of the transistor 311 is connected to the ground, and a collector of the transistor 311 is connected to an emitter of the transistor 312. A base of the transistor 312 is connected to the biasing circuit 50 with the resistor 313 as well as the switch 33 interposed therebetween. Meanwhile, the base of the transistor 312 is connected to the ground with a capacitor interposed therebetween, and is grounded in terms of the high frequency. A collector of the transistor 312 is connected to the power supply voltage terminal 150. That is to say, the power amplifier 31 includes the cascode-connected transistors 311 and 312.

The power amplifier 32 is an example of a third power amplifier, which includes transistors 321 and 322, and a resistor 323. The transistors 321 and 322 are n-type bipolar transistors (amplification elements), for example. A base of the transistor 321 is connected to the phase shifting circuit 30A with a capacitor as well as the power amplifier 31 interposed therebetween, an emitter of the transistor 321 is connected to the ground, and a collector of the transistor 321 is connected to an emitter of the transistor 322. A base of the transistor 322 is connected to the biasing circuit 50 with the resistor 323 as well as the switch 33 interposed therebetween. Meanwhile, the base of the transistor 322 is connected to the ground with a capacitor interposed therebetween, and is grounded in terms of the high frequency. A collector of the transistor 322 is connected to the power supply voltage terminal 150, and is connected to the synthetic circuit 40A with the capacitor 35 interposed therebetween. That is to say, the power amplifier 32 includes the cascode-connected transistors 321 and 322.

Note that the amplification circuit 1A does not always have to include the power amplifier 31. Alternatively, instead of the power amplifiers 31 and 32, the amplification circuit 1A may be provided with three or more cascade-connected power amplifiers including the power amplifier 32.

Since each of the power amplifiers 11, 12, 21, 22, 31, and 32 has the cascode-connected structure, the amplification circuit 1A can secure high amplification gain regarding the high-frequency signals in the millimeter-wave band and the sub-terahertz band.

The phase shifting circuit 30A is configured to distribute the high-frequency signal inputted from the signal input terminal 110, and to output the distributed signals to the power amplifiers 11, 21, and 31. In this instance, the phase shifting circuit 30A adjusts phases of the distributed signals. Note that the amplification circuit 1A does not always have to include the phase shifting circuit 30A.

The synthetic circuit 40A is connected to the output end of the power amplifier 12, the output end of the power amplifier 22, and an output end of the power amplifier 32, and is configured to synthesize the high-frequency signal outputted from the power amplifier 12, the high-frequency signal outputted from the power amplifier 22, and the high-frequency signal outputted from the power amplifier 32, and to output the synthesized high-frequency signal to the signal output terminal 120.

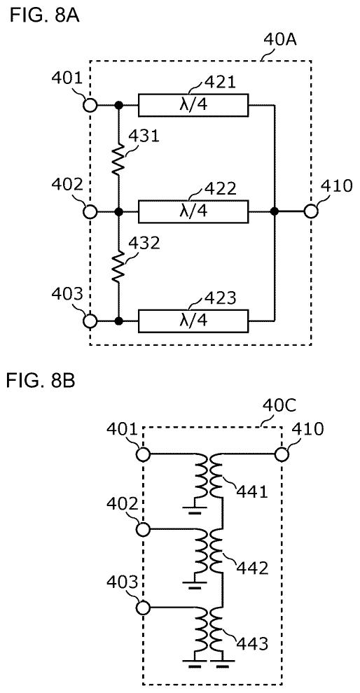

FIG. 8A is a circuit configuration diagram of the synthetic circuit 40A according to the Modified Example 2 of the embodiment. As shown in FIG. 8A, the synthetic circuit 40A includes input terminals 401, 402, and 403, the output terminal 410, λ/4 phase shifting lines 421, 422, and 423, and resistors 431 and 432. One end of the λ/4 phase shifting line 421 is connected to the input terminal 401, and another end of the λ/4 phase shifting line 421 is connected to the output terminal 410. One end of the λ/4 phase shifting line 422 is connected to the input terminal 402, and another end of the λ/4 phase shifting line 422 is connected to the output terminal 410. One end of the λ/4 phase shifting line 423 is connected to the input terminal 403, and another end of the λ/4 phase shifting line 423 is connected to the output terminal 410. One end of the resistor 431 is connected to the input terminal 401, and another end of the resistor 431 is connected to the input terminal 402. One end of the resistor 432 is connected to the input terminal 402, and another end of the resistor 432 is connected to the input terminal 403. The input terminal 401 is connected to the output end of the power amplifier 12 with the capacitor 15 interposed therebetween. The input terminal 402 is connected to the output end of the power amplifier 22 with the capacitor 25 interposed therebetween. The input terminal 403 is connected to the output end of the power amplifier 32 with the capacitor 35 interposed therebetween. The output terminal 410 is connected to the signal output terminal 120. According to the above-described configuration of the synthetic circuit 40A, the high-frequency signal outputted from the power amplifier 12, the high-frequency signal outputted from the power amplifier 22, and the high-frequency signal outputted from the power amplifier 32 are subjected to current synthesis by the synthetic circuit 40A, and the high-frequency signal subjected to the current synthesis is outputted from the signal output terminal 120. Here, the synthetic circuit 40A is not limited to the above-described circuit configuration and may instead be a synthetic circuit 40C according to Modified Example 3 described below, for example.

FIG. 8B is a circuit configuration diagram of the synthetic circuit 40C according to the Modified Example 3 of the embodiment. As shown in FIG. 8B, the synthetic circuit 40C includes the input terminals 401, 402, and 403, the output terminal 410, and transformers 441, 442, and 443. Each of the transformers 441, 442, and 443 includes a primary coil and a secondary coil. One end of the primary coil of the transformer 441 is connected to the input terminal 401, and another end thereof is connected to the ground. One end of the secondary coil of the transformer 441 is connected to the output terminal 410, and another end thereof is connected to one end of the secondary coil of the transformer 442. One end of the primary coil of the transformer 442 is connected to the input terminal 402, and another end thereof is connected to the ground. Another end of the secondary coil of the transformer 442 is connected to one end of the secondary coil of the transformer 443. One end of the primary coil of the transformer 443 is connected to the input terminal 403, and another end thereof is connected to the ground. Another end of the secondary coil of the transformer 443 is connected to the ground.

The input terminal 401 is connected to the output end of the power amplifier 12 with the capacitor 15 interposed therebetween. The input terminal 402 is connected to the output end of the power amplifier 22 with the capacitor 25 interposed therebetween. The input terminal 403 is connected to the output end of the power amplifier 32 with the capacitor 35 interposed therebetween. The output terminal 410 is connected to the signal output terminal 120. According to the above-described configuration of the synthetic circuit 40C, the high-frequency signal outputted from the power amplifier 12, the high-frequency signal outputted from the power amplifier 22, and the high-frequency signal outputted from the power amplifier 32 are subjected to voltage synthesis by the synthetic circuit 40C, and the high-frequency signal subjected to the voltage synthesis is outputted from the signal output terminal 120.

The biasing circuit 50 is configured to supply the first bias current to the power amplifiers 11 and 12, to supply the second bias current to the power amplifiers 21 and 22, and to supply a third bias current to the power amplifiers 31 and 32. The first bias current is supplied to the power amplifiers 11 and 12 with the switch 13 interposed therebetween, the second bias current is supplied to the power amplifiers 21 and 22 with the switch 23 interposed therebetween, and the third bias current is supplied to the power amplifiers 31 and 32 with the switch 33 interposed therebetween.

The switch 33 is an example of a third switch, which is connected to the digital control terminal 180 and configured to switch connection and disconnection between the biasing circuit 50 and the power amplifiers 31 and 32. To be more precise, the switch 33 includes a control terminal and two terminals. The control terminal is connected to the digital control terminal 180. One of the terminals is connected to the biasing circuit 50, and the other terminal is connected to the power amplifiers 31 and 32.

The switches 13, 23, and 33 are connected to the digital control terminals 160, 170, and 180, thus constituting a switching circuit that switches connection and disconnection of the biasing circuit 50 to and from the respective power amplifiers.

Here, the amplification circuit 1A may include the first logic circuit between the digital control terminals 160, 170, as well as 180 and the switch 13, the second logic circuit between the digital control terminals 160, 170, as well as 180 and the switch 23, and a third logic circuit between the digital control terminals 160, 170, as well as 180 and the switch 33. The first logic circuit converts the DCL signals (V1_EN, V2_EN, V3_EN) applied to the digital control terminals 160, 170, and 180 into a gate signal to be supplied to the switch 13. The second logic circuit converts the DCL signals (V1_EN, V2_EN, V3_EN) applied to the digital control terminals 160, 170, and 180 into a gate signal to be supplied to the switch 23. The third logic circuit converts the DCL signals (V1_EN, V2_EN, V3_EN) applied to the digital control terminals 160, 170, and 180 into a gate signal to be supplied to the switch 33.

For example, in the case of the DCL signals V1_EN=1, V2_EN=0, and V3_EN=0, the first logic circuit outputs the gate signal (Vg_1=1) to set the switch 13 to the conducting state, the second logic circuit outputs the gate signal (Vg_2=0) to set the switch 23 to the non-conducting state, and the third logic circuit outputs a gate signal (Vg_3=0) to set the switch 33 to the non-conducting state.

Meanwhile, in the case of the DCL signals V1_EN=0, V2_EN=1, and V3_EN=0, the first logic circuit outputs the gate signal (Vg_1=0) to set the switch 13 to the non-conducting state, the second logic circuit outputs the gate signal (Vg_2=1) to set the switch 23 to the conducting state, and the third logic circuit outputs the gate signal (Vg_3=0) to set the switch 33 to the non-conducting state.

In the meantime, in the case of the DCL signals V1_EN=0, V2_EN=0, and V3_EN=1, the first logic circuit outputs the gate signal (Vg_1=0) to set the switch 13 to the non-conducting state, the second logic circuit outputs the gate signal (Vg_2=0) to set the switch 23 to the non-conducting state, and the third logic circuit outputs a gate signal (Vg_3=1) to set the switch 33 to the conducting state.

Here, each digital control signal to be supplied to one of the digital control terminals 160, 170, and 180 may be the parallel data signal instead of the serial data signal such as the digital control signal in accordance with the source synchronous method. Parallel supply of the DCL signals V1_EN, V2_EN, and V3_EN to the respective digital control terminals 160, 170, and 180 makes it possible to switch on and off of the respective power amplifiers at high speed. Thus, it is possible to deal with the wide channel band width of the high-frequency signal in the millimeter-wave band and the sub-terahertz band.

### (4 Operation of Amplification Circuit 1A)

Next, an amplification operation of the amplification circuit 1A will be described.

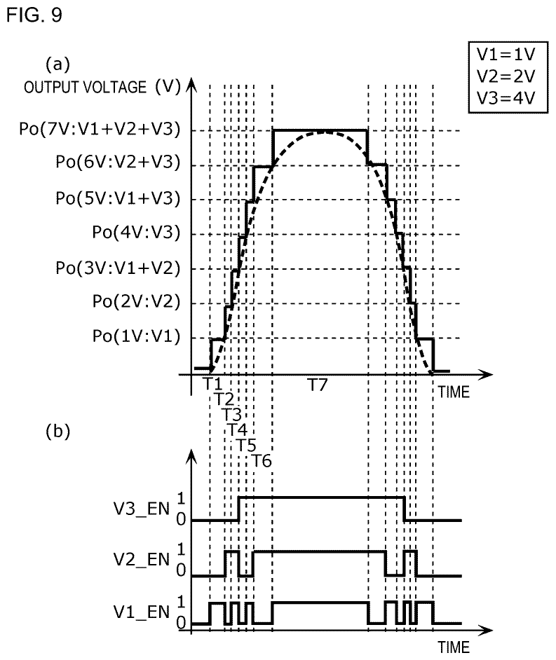

FIG. 9 shows diagrams depicting an envelope waveform, an output voltage, and an on-and-off relation of the switches of the amplification circuit 1A according to the Modified Example 2 of the embodiment. Part (a) of FIG. 9 depicts the envelope waveform (a dashed line) of the high-frequency signal to be inputted to the amplification circuit 1A and the output voltage (V) (the voltage component of the output power) of the amplification circuit 1A, and part (b) of FIG. 9 depicts waveforms of the DCL signals (V1_EN, V2_EN, V3_EN).

Here, an assumption is made in FIG. 9 that the power supply voltage V1=1 V, the power supply voltage V2=2 V, and the power supply voltage V3=4 V. That is to say, the power supply voltage V1 is lower than the power supply voltage V2, and the power supply voltage V2 is lower than the power supply voltage V3.

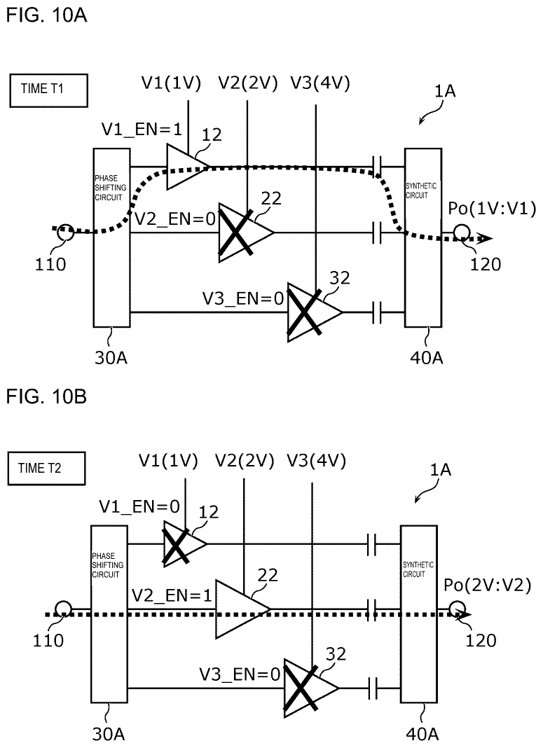

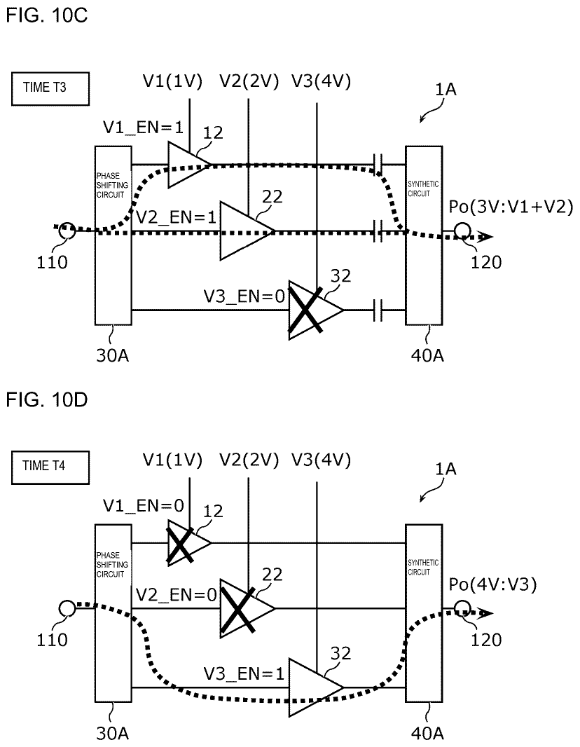

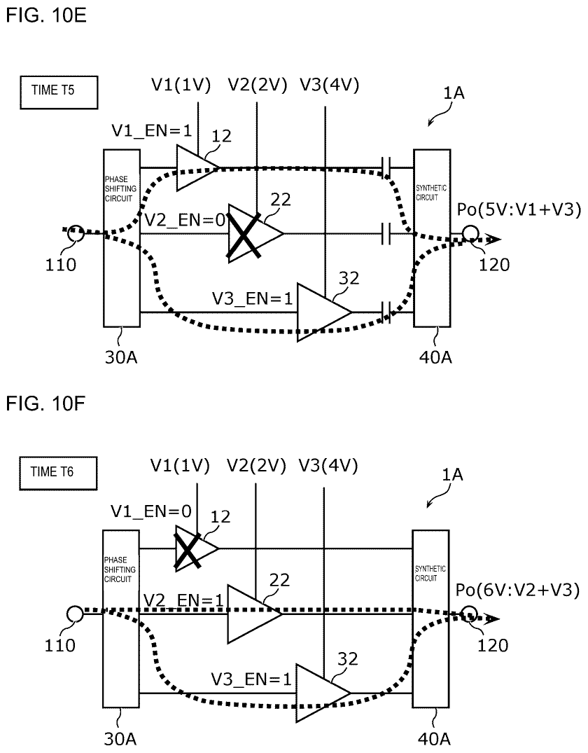

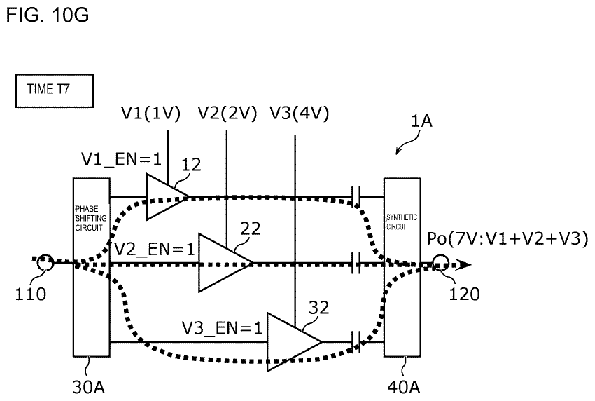

FIG. 10A is a circuit state diagram in a case where the high-frequency signal to be inputted to the amplification circuit 1A according to the Modified Example 2 of the embodiment has a first envelope value. Specifically, at time T1 when the envelope value of the high-frequency signal to be inputted to the amplification circuit 1A is equal to a first value, the switch 13 is set to the conducting state, the switch 23 is set to the non-conducting state, and the switch 33 is set to the non-conducting state by setting the DCL signals V1_EN=1, V2_EN=0, and V3_EN=0. Accordingly, the first bias current is supplied to the power amplifier 12 which is thus set to the on-state, the second bias current is not supplied to the power amplifier 22 which is thus set to the off-state, and the third bias current is not supplied to the power amplifier 32 which is thus set to the off-state. Hence, the power amplifier 12 outputs the output voltage Po_(1 V: V1), and the amplification circuit 1A outputs the output voltage Po_(1 V: V1).

FIG. 10B is a circuit state diagram in a case where the high-frequency signal to be inputted to the amplification circuit 1A according to the Modified Example 2 of the embodiment has a second envelope value. Specifically, at time T2 when the envelope value of the high-frequency signal to be inputted to the amplification circuit 1A is equal to a second value being larger than the first value, the switch 13 is set to the non-conducting state, the switch 23 is set to the conducting state, and the switch 33 is set to the non-conducting state by setting the DCL signals V1_EN=0, V2_EN=1, and V3_EN=0. Accordingly, the first bias current is not supplied to the power amplifier 12 which is thus set to the off-state, the second bias current is supplied to the power amplifier 22 which is thus set to the on-state, and the third bias current is not supplied to the power amplifier 32 which is thus set to the off-state. Hence, the power amplifier 22 outputs the output voltage Po_(2 V: V2), and the amplification circuit 1A outputs the output voltage Po_(2 V: V2).

FIG. 10C is a circuit state diagram in a case where the high-frequency signal to be inputted to the amplification circuit 1A according to the Modified Example 2 of the embodiment has a third envelope value. Specifically, at time T3 when the envelope value of the high-frequency signal to be inputted to the amplification circuit 1A is equal to a third value being larger than the second value, the switch 13 is set to the conducting state, the switch 23 is set to the conducting state, and the switch 33 is set to the non-conducting state by setting the DCL signals V1_EN=1, V2_EN=1, and V3_EN=0. Accordingly, the first bias current is supplied to the power amplifier 12 which is thus set to the on-state, the second bias current is supplied to the power amplifier 22 which is thus set to the on-state, and the third bias current is not supplied to the power amplifier 32 which is thus set to the off-state. Hence, the power amplifier 12 outputs the output voltage Po_(1 V: V1) and the power amplifier 22 outputs the output voltage Po_(2 V: V2). The output voltage Po_(1 V: V1) and the output voltage Po_(2 V: V2) are synthesized by the synthetic circuit 40A, and the amplification circuit 1A outputs the output voltage Po_(3 V: V1+V2).

FIG. 10D is a circuit state diagram in a case where the high-frequency signal to be inputted to the amplification circuit 1A according to the Modified Example 2 of the embodiment has a fourth envelope value. Specifically, at time T4 when the envelope value of the high-frequency signal to be inputted to the amplification circuit 1A is equal to a fourth value being larger than the third value, the switch 13 is set to the non-conducting state, the switch 23 is set to the non-conducting state, and the switch 33 is set to the conducting state by setting the DCL signals V1_EN=0, V2_EN=0, and V3_EN=1. Accordingly, the first bias current is not supplied to the power amplifier 12 which is thus set to the off-state, the second bias current is not supplied to the power amplifier 22 which is thus set to the off-state, and the third bias current is supplied to the power amplifier 32 which is thus set to the on-state. Hence, the power amplifier 32 outputs the output voltage Po_(4 V: V3), and the amplification circuit 1A outputs the output voltage Po_(4 V: V3).

FIG. 10E is a circuit state diagram in a case where the high-frequency signal to be inputted to the amplification circuit 1A according to the Modified Example 2 of the embodiment has a fifth envelope value. Specifically, at time T5 when the envelope value of the high-frequency signal to be inputted to the amplification circuit 1A is equal to a fifth value being larger than the fourth value, the switch 13 is set to the conducting state, the switch 23 is set to the non-conducting state, and the switch 33 is set to the conducting state by setting the DCL signals V1_EN=1, V2_EN=0, and V3_EN=1. Accordingly, the first bias current is supplied to the power amplifier 12 which is thus set to the on-state, the second bias current is not supplied to the power amplifier 22 which is thus set to the off-state, and the third bias current is supplied to the power amplifier 32 which is thus set to the on-state. Hence, the power amplifier 12 outputs the output voltage Po_(1 V: V1) and the power amplifier 32 outputs the output voltage Po_(4 V: V3). The output voltage Po_(1 V: V1) and the output voltage Po_(4 V: V3) are synthesized by the synthetic circuit 40A, and the amplification circuit 1A outputs the output voltage Po_(5 V: V1+V3).

FIG. 10F is a circuit state diagram in a case where the high-frequency signal to be inputted to the amplification circuit 1A according to the Modified Example 2 of the embodiment has a sixth envelope value. Specifically, at time T6 when the envelope value of the high-frequency signal to be inputted to the amplification circuit 1A is equal to a sixth value being larger than the fifth value, the switch 13 is set to the non-conducting state, the switch 23 is set to the conducting state, and the switch 33 is set to the conducting state by setting the DCL signals V1_EN=0, V2_EN=1, and V3_EN=1. Accordingly, the first bias current is not supplied to the power amplifier 12 which is thus set to the off-state, the second bias current is supplied to the power amplifier 22 which is thus set to the on-state, and the third bias current is supplied to the power amplifier 32 which is thus set to the on-state. Hence, the power amplifier 22 outputs the output voltage Po_(2 V: V2) and the power amplifier 32 outputs the output voltage Po_(4 V: V3). The output voltage Po_(2 V: V2) and the output voltage Po_(4 V: V3) are synthesized by the synthetic circuit 40A, and the amplification circuit 1A outputs the output voltage Po_(6 V: V2+V3).

FIG. 10G is a circuit state diagram in a case where the high-frequency signal to be inputted to the amplification circuit 1A according to the Modified Example 2 of the embodiment has a seventh envelope value. Specifically, at time T7 when the envelope value of the high-frequency signal to be inputted to the amplification circuit 1A is equal to a seventh value being larger than the sixth value, the switch 13 is set to the conducting state, the switch 23 is set to the conducting state, and the switch 33 is set to the conducting state by setting the DCL signals V1_EN=1, V2_EN=1, and V3_EN=1. Accordingly, the first bias current is supplied to the power amplifier 12 which is thus set to the on-state, the second bias current is supplied to the power amplifier 22 which is thus set to the on-state, and the third bias current is supplied to the power amplifier 32 which is thus set to the on-state. Hence, the power amplifier 12 outputs the output voltage Po_(1 V: V1), the power amplifier 22 outputs the output voltage Po_(2 V: V2) and the power amplifier 32 outputs the output voltage Po_(4 V: V3). The output voltage Po_(1 V: V1), the output voltage Po_(2 V: V2), and the output voltage Po_(4 V: V3) are synthesized by the synthetic circuit 40A, and the amplification circuit 1A outputs the output voltage Po_(7 V: V1+V2+V3).

According to the above-described operation of the amplification circuit 1A, the on-off operations of the respective power amplifiers are executed so as to correspond to the envelope value of the high-frequency signal to be inputted to the amplification circuit 1A in the state where the power supply voltage V1 being the direct-current voltage is constantly supplied to the power amplifiers 11 and 12, the power supply voltage V2 being the direct-current voltage is constantly supplied to the power amplifiers 21 and 22, and the power supply voltage V3 being the direct-current voltage is constantly supplied to the power amplifiers 31 and 32. In this instance, the power supply voltages to be supplied to the power amplifiers 12, 22, and 32 include three types of the power supply voltages V1, V2, and V3, respectively. Nonetheless, when the amplification circuit 1A is regarded as a single power amplifier, the power supply voltages to be supplied to the amplification circuit 1A can be seven types of the power supply voltages V1, V2, V3, (V1+V2), (V1+V3), (V2+V3), and (V1+V2+V3). Accordingly, the power supply voltage corresponding to the envelope signal is supplied to the amplification circuit 1A at high accuracy and high speed without blunting the waveform, so that efficiency and gain of the amplification circuit 1A can be improved.

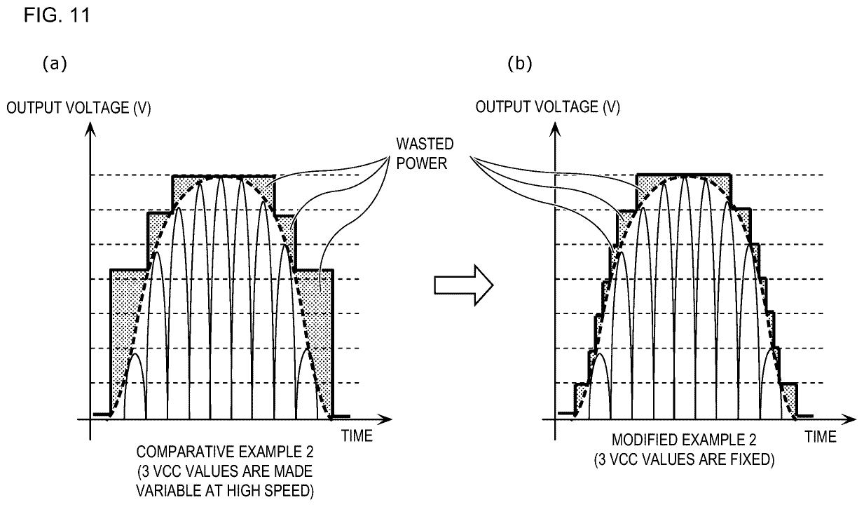

FIG. 11 is a diagram showing relations between envelope waveforms and output voltages of amplification circuits according to the Modified Example 2 of the embodiment and Comparative Example 2. Part (a) of FIG. 11 shows the relation between the envelope waveform and the output voltage (the voltage component of the output power) of the amplification circuit according to the Comparative Example 2, and part (b) of FIG. 11 shows the relation between the envelope waveform and the output voltage (the voltage component of the output power) of the amplification circuit 1A according to the Modified Example 2.

Here, as compared to the amplification circuit 501 according to the Comparative Example 1, the amplification circuit according to the Comparative Example 2 is additionally provided with the power amplifiers 31 and 32, and has such a configuration that the power supply voltages V1, V2, and V3 having different voltage levels from one another are variably supplied to the power amplifiers 11, 12, 21, 22, 31, and 32 based on the envelope signal.

As shown in part (a) of FIG. 11, in the amplification circuit according to the Comparative Example 2, one of the power supply voltages V1, V2, and V3 is selected and supplied to the amplification circuit so as to correspond to the envelope value of the high-frequency signal. The output voltages of the amplification circuit therefore have three types of values.

In the meantime, as shown in part (b) of FIG. 11, in the amplification circuit 1A according to the Modified Example 2, on-off combinations (7 ways) of the power amplifiers 12, 22, and 32 are switched so as to correspond to the envelope value of the high-frequency signal. The output voltages of the amplification circuit 1A can therefore have seven types of values.

That is to say, the amplification circuit 1A according to the Modified Example 2 can amplify the high-frequency signal at higher accuracy (with more stages) so as to correspond to the envelope value of the high-frequency signal as compared to the amplification circuit according to the Comparative Example 2 even though these amplification circuits have the same three types of set values of the power supply voltage. For this reason, as shown in FIG. 11, the amplification circuit 1A according to the Modified Example 2 can reduce an amount of wasted power corresponding to a difference between the output voltage and the envelope value as compared to the amplification circuit according to the Comparative Example 2.

Here, in the case where the power supply voltage V1 is lower than the power supply voltage V2 and the power supply voltage V2 is lower than the power supply voltage V3, the size of the amplification transistor included in the power amplifier 22 may be larger than the size of the amplification transistor included in the power amplifier 12, and the size of the amplification transistor included in the power amplifier 32 may be larger than the size of the amplification transistor included in the power amplifier 22.

According to this configuration, it is possible to execute the amplification operations across the entire signal range from a small signal range, a medium signal range, and a large signal range without causing the signal distortion.

Meanwhile, in the case where the power supply voltage V1 is lower than the power supply voltage V2 and the power supply voltage V2 is lower than the power supply voltage V3, a cross-sectional area of wiring that connects the power amplifier 22 to the power supply voltage terminal 140 may be larger than a cross-sectional area of wiring that connects the power amplifier 12 to the power supply voltage terminal 130, and a cross-sectional area of wiring that connects the power amplifier 32 to the power supply voltage terminal 150 may be larger than the cross-sectional area of the wiring that connects the power amplifier 22 to the power supply voltage terminal 140.

According to this configuration, it is possible to suppress waveform blunting of the power supply voltages V1, V2, and V3 more appropriately.

According to the amplification circuit 1A of the present modified example, the power supply voltage V1 being the direct-current voltage is constantly supplied to the power amplifiers 11 and 12, the power supply voltage V2 being the direct-current voltage is constantly supplied to the power amplifiers 21 and 22, and the power supply voltage V3 being the direct-current voltage is constantly supplied to the power amplifiers 31 and 32. That is to say, the direct-current voltage is constantly applied to power supply voltage supply wiring that connects the power supply voltage terminals 130, 140, and 150 to the respective power amplifiers. Accordingly, it is possible to keep the waveforms of the power supply voltages V1, V2, and V3 from being blunted by wiring capacitance of the power supply voltage supply wiring. In the meantime, switching the presence or absence of the supply of the bias current to be supplied to each power amplifier is equivalent to making the power supply voltage to be supplied to the power amplifier being in the on-state variable by using the digital control signals based on the envelope signal. Thus, it is possible to provide the amplification circuit 1A that suppresses deterioration of the amplification characteristics when using the digital ET.

### (5 Effects and Others)

As described above, the amplification circuit 1 according to the present embodiment includes the power supply voltage terminal 130 that receives the power supply voltage V1 being the direct-current voltage, the power supply voltage terminal 140 that receives the power supply voltage V2 being the direct-current voltage having the different voltage level from that of the power supply voltage V1, the digital control terminals 160 and 170 that receive the digital control signals based on the envelope signal, the power amplifier 12 connected to the power supply voltage terminal 130, the power amplifier 22 connected to the power supply voltage terminal 140, the synthetic circuit 40 connected to the output end of the power amplifier 12 and the output end of the power amplifier 22, the biasing circuit 50 configured to supply the first bias current to the power amplifier 12 and to supply the second bias current to the power amplifier 22, and the switching circuit (the switches 13 and 23) connected to the digital control terminals 160 and 170 and configured to switch connection and disconnection between the biasing circuit 50 and the power amplifier 12 and to switch connection and disconnection between the biasing circuit 50 and the power amplifier 22. Each of the power amplifiers 12 and 22 includes the multiple cascode-connected amplification transistors.

According to this configuration, the power supply voltage V1 being the direct-current voltage is constantly applied to the power amplifier 12, and the power supply voltage V2 being the direct-current voltage is constantly applied to the power amplifier 22. That is to say, the direct-current voltage is constantly applied to the power supply voltage supply wiring that connects the power supply voltage terminals 130 and 140 to the respective power amplifiers. Accordingly, it is possible to keep the waveforms of the power supply voltages V1 and V2 from being blunted by the wiring capacitance of the power supply voltage supply wiring. In the meantime, switching the presence or absence of the supply of the bias current to be supplied to each power amplifier based on the envelope signal is equivalent to making the power supply voltage to be supplied to the power amplifier being in the on-state variable by using the digital control signals based on the envelope signal. Thus, it is possible to suppress deterioration of the amplification characteristics when using the ET.

Meanwhile, in the amplification circuit 1, for example, each of the power supply voltages V1 and V2 need not be changed based on the envelope signal.

According to this configuration, the direct-current voltage is constantly applied to the power supply voltage supply wiring that connects the power supply voltage terminals 130 and 140 to the respective power amplifiers, and it is possible to keep the waveforms of the power supply voltages V1 and V2 from being blunted by the wiring capacitance of the power supply voltage supply wiring.

In the meantime, in the amplification circuit 1, for example, each digital control signal may be a digital signal different from the serial data signal.

According to this configuration, the parallel supply of the digital control signals makes it possible to switch on and off of the power amplifiers at high speed. Thus, it is possible to deal with the wide channel band width of the high-frequency signal in the millimeter-wave band and the sub-terahertz band.

Meanwhile, in the amplification circuit 1, for example, the switching circuit includes the switch 13 connected to the digital control terminal 160 and configured to switch connection and disconnection between the biasing circuit 50 and the power amplifier 12, and the switch 23 connected to the digital control terminal 170 and configured to switch connection and disconnection between the biasing circuit 50 and the power amplifier 22. Here, the power supply voltage V1 is lower than the power supply voltage V2. In this instance, when the envelope value indicating the magnitude of the envelope signal is equal to the first value, the switch 13 is set to the conducting state and the switch 23 is set to the non-conducting state. Meanwhile, when the envelope value is equal to the second value being larger than the first value, the switch 13 is set to the non-conducting state and the switch 23 is set to the conducting state. In the meantime, when the envelope value is equal to the third value being larger than the second value, the switch 13 is set to the conducting state and the switch 23 is set to the conducting state.

According to this configuration, the on-off operations of the respective power amplifiers are executed so as to correspond to the envelope value of the high-frequency signal to be inputted to the amplification circuit 1 in the state where the power supply voltage V1 is constantly supplied to the power amplifier 12 and the power supply voltage V2 is constantly supplied to the power amplifier 22. In this instance, the power supply voltages to be supplied to the power amplifiers 12 and 22 include two types of the power supply voltages V1 and V2. Nonetheless, when the amplification circuit 1 is regarded as a single power amplifier, the power supply voltages to be supplied to the amplification circuit 1 include three types of the power supply voltages V1, V2, and (V1+V2). Accordingly, the power supply voltage corresponding to the envelope signal is supplied to the amplification circuit 1 at high accuracy and high speed, so that efficiency and gain of the amplification circuit 1 can be improved.

In the meantime, the amplification circuit 1 further includes the signal input terminal 110 to which the high-frequency signal is inputted, for example. The power amplifier 12 includes the transistors 121 and 122. The base of the transistor 121 is connected to the signal input terminal 110. The emitter of the transistor 121 is connected to the ground. The collector of the transistor 121 is connected to the emitter of the transistor 122. The collector of the transistor 122 is connected to the power supply voltage terminal 130 and the synthetic circuit 40. The base of the transistor 122 is connected to the switch 13. The power amplifier 22 includes the transistors 221 and 222. The base of the transistor 221 is connected to the signal input terminal 110. The emitter of the transistor 221 is connected to the ground. The collector of the transistor 221 is connected to the emitter of the transistor 222. The collector of the transistor 222 is connected to the power supply voltage terminal 140 and the synthetic circuit 40. The base of the transistor 222 is connected to the switch 23.

According to this configuration, since each of the power amplifiers 12 and 22 has the cascode-connected structure, the amplification circuit 1 can secure high amplification gain regarding the high-frequency signals in the millimeter-wave band and the sub-terahertz band.

Meanwhile, in the amplification circuit 1, for example, the power supply voltage V1 may be lower than the power supply voltage V2, and the size of each of the multiple amplification transistors included in the power amplifier 22 may be larger than the size of each of the multiple amplification transistors included in the power amplifier 12.

According to this configuration, it is possible to execute the amplification operations across the entire signal range from the small signal range to the large signal range while suppressing the signal distortion.

In the meantime, in the amplification circuit 1, for example, the power supply voltage V1 may be lower than the power supply voltage V2, and the cross-sectional area of the wiring that connects the power amplifier 22 to the power supply voltage terminal 140 may be larger than the cross-sectional area of the wiring that connects the power amplifier 12 to the power supply voltage terminal 130.

According to this configuration, it is possible to suppress waveform blunting of the power supply voltages V1 and V2.

On the other hand, in addition to the amplification circuit 1 according to the embodiment, the amplification circuit 1A according to the Modified Example 2 may include the power supply voltage terminal 150 that receives the power supply voltage V3 having a different voltage level from those of the power supply voltages V1 and V2, and the power amplifier 32 connected to the power supply voltage terminal 150. The synthetic circuit 40A may be connected to the output end of power amplifier 12, the output end of the power amplifier 22, and the output end of the power amplifier 32. The biasing circuit 50 may supply the first bias current to the power amplifier 12, supply the second bias current to the power amplifier 22, and supply the third bias current to the power amplifier 32. The switching circuit may be connected to the digital control terminals 160, 170, and 180, and configured to switch connection and disconnection between the biasing circuit 50 and the power amplifier 12, to switch connection and disconnection between the biasing circuit 50 and the power amplifier 22, and to switch connection and disconnection between the biasing circuit 50 and the power amplifier 32. The power amplifier 32 may include the multiple cascode-connected amplification transistors.

According to this configuration, the power supply voltage V1 being the direct-current voltage is constantly supplied to the power amplifier 12, the power supply voltage V2 being the direct-current voltage is constantly supplied to the power amplifier 22, and the power supply voltage V3 being the direct-current voltage is constantly supplied to the power amplifier 32. That is to say, the direct-current voltage is constantly applied to power supply voltage supply wiring that connects the power supply voltage terminals 130, 140, and 150 to the respective power amplifiers.

Accordingly, it is possible to keep the waveforms of the power supply voltages V1, V2, and V3 from being blunted by the wiring capacitance of the power supply voltage supply wiring. In the meantime, switching the presence or absence of the supply of the bias current to be supplied to each power amplifier is equivalent to making the power supply voltage to be supplied to the power amplifier being in the on-state variable by using the digital control signals based on the envelope signal. Thus, it is possible to suppress deterioration of the amplification characteristics when using the ET.

In the meantime, in the amplification circuit 1A, for example, the switching circuit includes the switch 13 connected to the digital control terminal 160 and configured to switch connection and disconnection between the biasing circuit 50 and the power amplifier 12, the switch 23 connected to the digital control terminal 170 and configured to switch connection and disconnection between the biasing circuit 50 and the power amplifier 22, and the switch 33 connected to the digital control terminal 180 and configured to switch connection and disconnection between the biasing circuit 50 and the power amplifier 32. The power supply voltage V1 is lower than the power supply voltage V2 and the power supply voltage V2 is lower than the power supply voltage V3. In this instance, when the envelope value indicating the magnitude of the envelope signal is equal to the first value, the switch 13 is set to the conducting state, the switch 23 is set to the non-conducting state, and the switch 33 is set to the non-conducting state. Meanwhile, when the envelope value is equal to the second value being larger than the first value, the switch 13 is set to the non-conducting state, the switch 23 is set to the conducting state, and the switch 33 is set to the non-conducting state. In the meantime, when the envelope value is equal to the third value being larger than the second value, the switch 13 is set to the conducting state, the switch 23 is set to the conducting state, and the switch 33 is set to the non-conducting state. Meanwhile, when the envelope value is equal to the fourth value being larger than the third value, the switch 13 is set to the non-conducting state, the switch 23 is set to the non-conducting state, and the switch 33 is set to the conducting state. In the meantime, when the envelope value is equal to the fifth value being larger than the fourth value, the switch 13 is set to the conducting state, the switch 23 is set to the non-conducting state, and the switch 33 is set to the conducting state. Meanwhile, when the envelope value is equal to the sixth value being larger than the fifth value, the switch 13 is set to the non-conducting state, the switch 23 is set to the conducting state, and the switch 33 is set to the conducting state. In the meantime, when the envelope value is equal to the seventh value being larger than the sixth value, the switch 13 is set to the conducting state, the switch 23 is set to the conducting state, and the switch 33 is set to the conducting state.

According to this configuration, the on-off operations of the respective power amplifiers are executed so as to correspond to the envelope value of the high-frequency signal to be inputted to the amplification circuit 1A in the state where the power supply voltage V1 is constantly supplied to the power amplifier 12, the power supply voltage V2 is constantly supplied to the power amplifier 22, and the power supply voltage V3 is constantly supplied to the power amplifier 32. In this instance, the power supply voltages to be supplied to the power amplifiers 12, 22, and 32 include three types of the power supply voltages V1, V2, and V3, respectively. Nonetheless, when the amplification circuit 1A is regarded as a single power amplifier, the power supply voltages to be supplied to the amplification circuit 1A can be seven types of the power supply voltages V1, V2, V3, (V1+V2), (V1+V3), (V2+V3), and (V1+V2+V3). Accordingly, the power supply voltage corresponding to the envelope signal is supplied to the amplification circuit 1A at high accuracy and high speed, so that efficiency and gain of the amplification circuit 1A can be improved.

Meanwhile, in the amplification circuit 1A, for example, the power supply voltage V1 may be lower than the power supply voltage V2, the power supply voltage V2 may be lower than the power supply voltage V3, the size of each of the multiple amplification transistors included in the power amplifier 22 may be larger than the size of each of the multiple amplification transistors included in the power amplifier 12, and the size of each of the multiple amplification transistors included in the power amplifier 32 may be larger than the size of each of the multiple amplification transistors included in the power amplifier 22.

According to this configuration, it is possible to execute the amplification operations across the entire signal range from the small signal range to the large signal range while suppressing the signal distortion.

In the meantime, in the amplification circuit 1A, for example, the power supply voltage V1 may be lower than the power supply voltage V2, the power supply voltage V2 may be lower than the power supply voltage V3, the cross-sectional area of the wiring that connects the power amplifier 22 to the power supply voltage terminal 140 may be larger than the cross-sectional area of the wiring that connects the power amplifier 12 to the power supply voltage terminal 130, and the cross-sectional area of the wiring that connects the power amplifier 32 to the power supply voltage terminal 150 may be larger than the cross-sectional area of the wiring that connects the power amplifier 22 to the power supply voltage terminal 140.

According to this configuration, it is possible to suppress waveform blunting of the power supply voltages V1, V2, and V3.

On the other hand, the communication device 4 according to the present embodiment includes the signal processing circuit 3 that processes the high-frequency signal, and the amplification circuit 1 that transmits the high-frequency signal between the signal processing circuit 3 and the antenna.

According to this configuration, the communication device 4 can realize the effects of the amplification circuit 1.

### OTHER EMBODIMENTS

The amplification circuit and the communication device according to the present disclosure have been described above based on the embodiment and the modified examples. However, the amplification circuit and the communication device according to the present disclosure are not limited to the embodiment and the modified examples described above. The present disclosure also encompasses other embodiments realized by combining arbitrary components among the embodiment and the modified examples described above, modified examples obtained by subjecting the embodiment and the modified examples described above to various modifications conceived by a person skilled in the art within the range not departing from the gist of the present disclosure, and various instruments embedding the amplification circuit and the communication device described above.

For example, in the circuit configuration of any of the amplification circuits and the communication device of the embodiment and the modified examples, another circuit element, wiring, or the like may be inserted between a path that connects each circuit element and a signal path disclosed in the drawings.

The characteristics of the amplification circuits and the communication device explained based on the embodiment and the modified examples described above are defined as follows.
<1> An amplification circuit including: a first power supply voltage terminal that receives a first power supply voltage being a direct-current voltage; a second power supply voltage terminal that receives a second power supply voltage being a direct-current voltage and having a different voltage level from a voltage level of the first power supply voltage; a digital control terminal that receives a digital control signal based on an envelope signal; a first power amplifier connected to the first power supply voltage terminal; a second power amplifier connected to the second power supply voltage terminal; a synthetic circuit connected to an output end of the first power amplifier and an output end of the second power amplifier; a biasing circuit configured to supply a first bias current to the first power amplifier and to supply a second bias current to the second power amplifier; and a switching circuit connected to the digital control terminal and configured to switch connection and disconnection between the biasing circuit and the first power amplifier and to switch connection and disconnection between the biasing circuit and the second power amplifier, in which each of the first power amplifier and the second power amplifier includes a plurality of cascode-connected amplification elements.
<2> The amplification circuit according to <1>, in which each of the first power supply voltage and the second power supply voltage is not changed based on the envelope signal.
<3> The amplification circuit according to <1>, in which the digital control signal is a digital signal different from a serial data signal.
<4> The amplification circuit according to any one of <1> to <3>, in which the switching circuit includes a first switch connected to the digital control terminal and configured to switch connection and disconnection between the biasing circuit and the first power amplifier, and a second switch connected to the digital control terminal and configured to switch connection and disconnection between the biasing circuit and the second power amplifier, the first power supply voltage is lower than the second power supply voltage, when an envelope value indicating a magnitude of the envelope signal of a high-frequency signal to be inputted to the amplification circuit is equal to a first value, the first switch is set to a conducting state and the second switch is set to a non-conducting state, when the envelope value is equal to a second value being larger than the first value, the first switch is set to the non-conducting state and the second switch is set to the conducting state, and when the envelope value is equal to a third value being larger than the second value, the first switch is set to the conducting state and the second switch is set to the conducting state.
<5> The amplification circuit according to any one of <1> to <4>, further including: a signal input terminal to which a high-frequency signal is inputted, in which the first power amplifier includes a first amplification element provided with a first control terminal, a first terminal, and a second terminal, and a second amplification element provided with a second control terminal, a third terminal, and a fourth terminal, the first control terminal is connected to the signal input terminal, the first terminal is connected to ground, the second terminal is connected to the third terminal, the fourth terminal is connected to the first power supply voltage terminal and the synthetic circuit, the second control terminal is connected to the switching circuit, the second power amplifier includes a third amplification element provided with a third control terminal, a fifth terminal, and a sixth terminal, and a fourth amplification element provided with a fourth control terminal, a seventh terminal, and an eighth terminal, the third control terminal is connected to the signal input terminal, the fifth terminal is connected to the ground, the sixth terminal is connected to the seventh terminal, the eighth terminal is connected to the second power supply voltage terminal and the synthetic circuit, and the fourth control terminal is connected to the switching circuit.
<6> The amplification circuit according to any one of <1> to <5>, in which the first power supply voltage is lower than the second power supply voltage, and a size of each of the plurality of amplification elements included in the second power amplifier is larger than a size of each of the plurality of amplification elements included in the first power amplifier.
<7> The amplification circuit according to any one of <1> to <6>, in which the first power supply voltage is lower than the second power supply voltage, and a cross-sectional area of wiring that connects the second power amplifier to the second power supply voltage terminal is larger than a cross-sectional area of wiring that connects the first power amplifier to the first power supply voltage terminal.
<8> The amplification circuit according to any one of <1> to <7>, further including: a third power supply voltage terminal that receives a third power supply voltage having a different voltage level from the voltage levels of the first power supply voltage and the second power supply voltage; and a third power amplifier connected to the third power supply voltage terminal, in which the synthetic circuit is connected to the output end of the first power amplifier, the output end of the second power amplifier, and an output end of the third power amplifier, the biasing circuit supplies the first bias current to the first power amplifier, supplies the second bias current to the second power amplifier, and supplies a third bias current to the third power amplifier, the switching circuit is connected to the digital control terminal, and switches connection and disconnection between the biasing circuit and the first power amplifier, switches connection and disconnection between the biasing circuit and the second power amplifier, and switches connection and disconnection between the biasing circuit and the third power amplifier, and the third power amplifier includes a plurality of cascode-connected amplification elements.
<9> The amplification circuit according to <8>, in which the switching circuit includes a first switch connected to the digital control terminal and configured to switch connection and disconnection between the biasing circuit and the first power amplifier, a second switch connected to the digital control terminal and configured to switch connection and disconnection between the biasing circuit and the second power amplifier, and a third switch connected to the digital control terminal and configured to switch connection and disconnection between the biasing circuit and the third power amplifier, the first power supply voltage is lower than the second power supply voltage and the second power supply voltage is lower than the third power supply voltage, when an envelope value indicating a magnitude of the envelope signal of a high-frequency signal to be inputted to the amplification circuit is equal to a first value, the first switch is set to a conducting state, the second switch is set to a non-conducting state, and the third switch is set to the non-conducting state, when the envelope value is equal to a second value being larger than the first value, the first switch is set to the non-conducting state, the second switch is set to the conducting state, and the third switch is set to the non-conducting state, when the envelope value is equal to a third value being larger than the second value, the first switch is set to the conducting state, the second switch is set to the conducting state, and the third switch is set to the non-conducting state, when the envelope value is equal to a fourth value being larger than the third value, the first switch is set to the non-conducting state, the second switch is set to the non-conducting state, and the third switch is set to the conducting state, when the envelope value is equal to a fifth value being larger than the fourth value, the first switch is set to the conducting state, the second switch is set to the non-conducting state, and the third switch is set to the conducting state, when the envelope value is equal to a sixth value being larger than the fifth value, the first switch is set to the non-conducting state, the second switch is set to the conducting state, and the third switch is set to the conducting state, and when the envelope value is equal to a seventh value being larger than the sixth value, the first switch is set to the conducting state, the second switch is set to the conducting state, and the third switch is set to the conducting state.
<10> The amplification circuit according to <8> or <9>, in which the first power supply voltage is lower than the second power supply voltage, the second power supply voltage is lower than the third power supply voltage, a size of each of the plurality of amplification elements included in the second power amplifier is larger than a size of each of the plurality of amplification elements included in the first power amplifier, and a size of each of the plurality of amplification elements included in the third power amplifier is larger than the size of each of the plurality of amplification elements included in the second power amplifier.
<11> The amplification circuit according to any one of <8> to <10>, in which the first power supply voltage is lower than the second power supply voltage, the second power supply voltage is lower than the third power supply voltage, a cross-sectional area of wiring that connects the second power amplifier to the second power supply voltage terminal is larger than a cross-sectional area of wiring that connects the first power amplifier to the first power supply voltage terminal, and a cross-sectional area of wiring that connects the third power amplifier to the third power supply voltage terminal is larger than the cross-sectional area of the wiring that connects the second power amplifier to the second power supply voltage terminal.
<12> A communication device including: a signal processing circuit that processes a high-frequency signal; and the amplification circuit according to any one of <1> to <11> that transmits the high-frequency signal between the signal processing circuit and an antenna.

The present disclosure can be widely used in communication instruments such as a cellular phone, as a power amplification circuit or a communication device to be disposed at a multi-band compatible front-end unit.
1, 1A, 501 amplification circuit
2, 2A, 502 tracker circuit
3 signal processing circuit
4, 4A communication device
11, 12, 21, 22, 31, 32 power amplifier
13, 23, 33 switch
15, 25, 35 capacitor
30, 30A phase shifting circuit
40, 40A, 40B, 40C synthetic circuit
50 biasing circuit
60, 60A discrete voltage generation circuit
70 voltage selection circuit
80, 80A digital control circuit
110 signal input terminal
111, 112, 121, 122, 211, 212, 221, 222, 311, 312, 321, 322 transistor
113, 123, 213, 223, 313, 323, 431, 432 resistor
120 signal output terminal
130, 140, 150 power supply voltage terminal
160, 170, 180 digital control terminal
401, 402, 403 input terminal
410 output terminal
421, 422, 423 λ/4 phase shifting line
441, 442, 443 transformer

1. An amplification circuit comprising:
a first power supply voltage terminal configured to receive a first power supply voltage being a direct-current voltage;
a second power supply voltage terminal configured to receive a second power supply voltage being a direct-current voltage and having a different voltage level from a voltage level of the first power supply voltage;
a digital control terminal configured to receive a digital control signal based on an envelope signal;
a first power amplifier connected to the first power supply voltage terminal;
a second power amplifier connected to the second power supply voltage terminal;
a synthetic circuit connected to an output end of the first power amplifier and an output end of the second power amplifier;
a biasing circuit configured to supply a first bias current to the first power amplifier and to supply a second bias current to the second power amplifier; and
a switching circuit connected to the digital control terminal and configured to selectively connect the biasing circuit to the first power amplifier and to selectively connect the biasing circuit to the second power amplifier,
wherein each of the first power amplifier and the second power amplifier comprises a plurality of cascode-connected amplification elements.

2. The amplification circuit according to claim 1, wherein each of the first power supply voltage and the second power supply voltage is not changed based on the envelope signal.

3. The amplification circuit according to claim 1, wherein the digital control signal is a digital signal different from a serial data signal.

4. The amplification circuit according to claim 1,
wherein the switching circuit comprises:
a first switch connected to the digital control terminal and configured to selectively connect the biasing circuit to the first power amplifier, and
a second switch connected to the digital control terminal and configured to selectively connect the biasing circuit to the second power amplifier,
wherein the first power supply voltage is lower than the second power supply voltage,
wherein when an envelope value indicating a magnitude of the envelope signal of a high-frequency signal to be inputted to the amplification circuit is equal to a first value, the first switch is set to a conducting state and the second switch is set to a non-conducting state,
wherein when the envelope value is equal to a second value being larger than the first value, the first switch is set to the non-conducting state and the second switch is set to the conducting state, and
wherein when the envelope value is equal to a third value being larger than the second value, the first switch is set to the conducting state and the second switch is set to the conducting state.

5. The amplification circuit according to claim 1, further comprising:
a signal input terminal to which a high-frequency signal is inputted,
wherein the first power amplifier comprises:
a first amplification element having a first control terminal, a first terminal, and a second terminal, and
a second amplification element having a second control terminal, a third terminal, and a fourth terminal,
wherein the first control terminal is connected to the signal input terminal,
wherein the first terminal is connected to ground,
wherein the second terminal is connected to the third terminal,
wherein the fourth terminal is connected to the first power supply voltage terminal and the synthetic circuit,
wherein the second control terminal is connected to the switching circuit,
wherein the second power amplifier comprises:
a third amplification element having a third control terminal, a fifth terminal, and a sixth terminal, and
a fourth amplification element having a fourth control terminal, a seventh terminal, and an eighth terminal,
wherein the third control terminal is connected to the signal input terminal,
wherein the fifth terminal is connected to the ground,
wherein the sixth terminal is connected to the seventh terminal,
wherein the eighth terminal is connected to the second power supply voltage terminal and the synthetic circuit, and
wherein the fourth control terminal is connected to the switching circuit.

6. The amplification circuit according to claim 1,
wherein the first power supply voltage is lower than the second power supply voltage, and
wherein a size of each of the plurality of amplification elements in the second power amplifier is larger than a size of each of the plurality of amplification elements in the first power amplifier.

7. The amplification circuit according to claim 1,
wherein the first power supply voltage is lower than the second power supply voltage, and
wherein a cross-sectional area of wiring that connects the second power amplifier to the second power supply voltage terminal is larger than a cross-sectional area of wiring that connects the first power amplifier to the first power supply voltage terminal.

8. The amplification circuit according to claim 1, further comprising:
a third power supply voltage terminal configured to receive a third power supply voltage having a different voltage level from the voltage levels of the first power supply voltage and the second power supply voltage; and
a third power amplifier connected to the third power supply voltage terminal,
wherein the synthetic circuit is connected to the output end of the first power amplifier, the output end of the second power amplifier, and an output end of the third power amplifier,
wherein the biasing circuit is configured to supply the first bias current to the first power amplifier, supply the second bias current to the second power amplifier, and supply a third bias current to the third power amplifier,
the switching circuit is connected to the digital control terminal, and is configured to selectively connect the biasing circuit to the first power amplifier, selectively connect the biasing circuit to the second power amplifier, and selectively connect the biasing circuit to the third power amplifier, and
wherein the third power amplifier comprises a plurality of cascode-connected amplification elements.

9. The amplification circuit according to claim 8,
wherein the switching circuit comprises:
a first switch connected to the digital control terminal and configured to selectively connect the biasing circuit to the first power amplifier,
a second switch connected to the digital control terminal and configured to selectively connect the biasing circuit to the second power amplifier, and
a third switch connected to the digital control terminal and configured to selectively connect the biasing circuit and the third power amplifier,
wherein the first power supply voltage is lower than the second power supply voltage and the second power supply voltage is lower than the third power supply voltage,
wherein when an envelope value indicating a magnitude of the envelope signal of a high-frequency signal to be inputted to the amplification circuit is equal to a first value, the first switch is set to a conducting state, the second switch is set to a non-conducting state, and the third switch is set to the non-conducting state,
wherein when the envelope value is equal to a second value being larger than the first value, the first switch is set to the non-conducting state, the second switch is set to the conducting state, and the third switch is set to the non-conducting state,
wherein when the envelope value is equal to a third value being larger than the second value, the first switch is set to the conducting state, the second switch is set to the conducting state, and the third switch is set to the non-conducting state,
wherein when the envelope value is equal to a fourth value being larger than the third value, the first switch is set to the non-conducting state, the second switch is set to the non-conducting state, and the third switch is set to the conducting state,
wherein when the envelope value is equal to a fifth value being larger than the fourth value, the first switch is set to the conducting state, the second switch is set to the non-conducting state, and the third switch is set to the conducting state,
wherein when the envelope value is equal to a sixth value being larger than the fifth value, the first switch is set to the non-conducting state, the second switch is set to the conducting state, and the third switch is set to the conducting state, and
wherein when the envelope value is equal to a seventh value being larger than the sixth value, the first switch is set to the conducting state, the second switch is set to the conducting state, and the third switch is set to the conducting state.

10. The amplification circuit according to claim 8,
wherein the first power supply voltage is lower than the second power supply voltage,
wherein the second power supply voltage is lower than the third power supply voltage,
wherein a size of each of the plurality of amplification elements included in the second power amplifier is larger than a size of each of the plurality of amplification elements included in the first power amplifier, and
wherein a size of each of the plurality of amplification elements included in the third power amplifier is larger than the size of each of the plurality of amplification elements included in the second power amplifier.

11. The amplification circuit according to claim 8,
wherein the first power supply voltage is lower than the second power supply voltage,
wherein the second power supply voltage is lower than the third power supply voltage,
wherein a cross-sectional area of wiring that connects the second power amplifier to the second power supply voltage terminal is larger than a cross-sectional area of wiring that connects the first power amplifier to the first power supply voltage terminal, and
wherein a cross-sectional area of wiring that connects the third power amplifier to the third power supply voltage terminal is larger than the cross-sectional area of the wiring that connects the second power amplifier to the second power supply voltage terminal.

12. A communication device comprising:
a signal processing circuit configured to process a high-frequency signal; and
the amplification circuit according to claim 1 configured to pass the high-frequency signal between the signal processing circuit and an antenna.
